(19) United States
(12) Patent Application Publication
(10) Pub. No.: US 2025/0185491 A1
(43) Pub. Date: Jun. 5, 2025

(54) DISPLAY DEVICE

(71) Applicant: LG Display Co., Ltd., Seoul (KR)

(72) Inventors: YongCheol KIM, Gimpo-si (KR); Sohee LEE, Paju-si (KR); Kyuil HAN, Paju-si (KR)

(73) Assignee: LG Display Co., Ltd., Seoul (KR)

(21) Appl. No.: 18/898,300

(22) Filed: Sep. 26, 2024

(30) Foreign Application Priority Data
Dec. 1, 2023 (KR) 10-2023-0172489

(51) Int. Cl. H10K 59/80; H10K 59/122; H10K 59/131; H10K 59/38; H10K 59/40

(52) U.S. Cl. CPC H10K 59/878; H10K 59/122; H10K 59/131; H10K 59/38; H10K 59/40; H10K 59/873; H10K 59/8792

(57) ABSTRACT

A display device can include a substrate having a first active area and a second active area, a planarization film disposed on the substrate, a first bank disposed on the planarization film, an anode disposed on the planarization film and a side surface of the first bank, a second bank disposed on the first bank and the anode while covering a part of the anode and the first bank, an organic layer and a cathode disposed on the anode, an encapsulation unit disposed on the cathode, a black matrix and a color filter layer disposed on the encapsulation unit, and an optical shutter disposed on the color filter layer of the second active area. In the second active area, the anode can include an extending area which partially extends in one direction to form a reflection area.

### CROSS-REFERENCE TO RELATED APPLICATIONS

This application claims priority to Korean Patent Application No. 10-2023-0172489 filed on Dec. 1, 2023, in the Korean Intellectual Property Office, the entire contents of which is hereby expressly incorporated by reference into the present application.

### BACKGROUND

### Field

The present disclosure relates to a display device.

### Discussion of the Related Art

Currently, in the full-scale information era, a field of a display device which visually expresses electrical information signals has been rapidly developed and studies are continued to improve performances of various display devices such as a thin-thickness, a light weight, and low power consumption.

Among various display devices, an electroluminescent display device is a self-emitting display device that does not need a separate light source, which is different from a liquid crystal display device. Therefore, the electroluminescent display device can be manufactured to have a light weight and a thin-thickness. Further, since the electroluminescent display device is driven at a low voltage so that it is advantageous not only in terms of power consumption, but also in terms of color implementation, a response speed, a viewing angle, a contrast ratio (CR). Therefore, it is expected to be utilized in various fields.

In the meantime, light emitted from an emission layer of the electroluminescent display device passes through various components of the electroluminescent display device to be released to the outside of the electroluminescent display device. However, some of the light emitted from the emission layer is trapped in the electroluminescent display device without being released to the outside of the electroluminescent display device so that the light extraction efficiency of the electroluminescent display device becomes an issue.

### SUMMARY OF THE DISCLOSURE

An object to be achieved by the present disclosure is to provide a display device which improves a light extraction efficiency.

Another object to be achieved by the present disclosure is to provide a display device in which reflected light is utilized as a reflection mode.

Still another object to be achieved by the present disclosure is to provide a display device in which a self-emission mode and a reflection mode are implemented in an always-on-display (AOD) driving area.

Another object to be achieved by the present disclosure is to provide a display device, which addresses the limitations and disadvantages associated with the related art.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device includes a substrate including a first active area and a second active area, a planarization film disposed on the substrate, a first bank disposed on the planarization film, an anode disposed on the planarization film and a side surface of the first bank, a second bank disposed on the first bank and the anode while covering a part of the anode and the first bank, an organic layer and a cathode disposed on the anode, an encapsulation unit disposed on the cathode, a black matrix and a color filter layer disposed on the encapsulation unit, and an optical shutter disposed on the color filter layer of the second active area, where in the second active area, the anode can include an extending area which partially extends in one direction to form a reflection area.

According to another aspect of the present disclosure, a display device includes a substrate having an always-on-display (AOD) driving area, a planarization film disposed on the substrate, a first bank disposed on the planarization film, an anode disposed on the planarization film and a side surface of the first bank, a second bank disposed on the first bank and the anode while covering a part of the anode and the first bank, an organic layer and a cathode disposed on the anode, an encapsulation unit disposed on the cathode, a black matrix and a color filter layer disposed on the encapsulation unit, and an optical shutter disposed on the color filter layer of the AOD driving area.

Other detailed matters of the example embodiments of the present disclosure are included in the detailed description and the drawings.

According to aspects of the present disclosure, the light extraction efficiency of the display device can be improved using a side mirror-type anode.

According to aspects of the present disclosure, a color filter layer and a black matrix are disposed on an encapsulation unit to remove a polarizer. Accordingly, the light extraction efficiency of the display device can be improved to implement low power.

According to aspects of the present disclosure, an always-on-display driving area is set in a part of a screen so that the information can be provided even in a state in which the display device is turned off.

According to aspects of the present disclosure, increased reflected light is utilized in a reflection mode in the ADO driving area by applying OLED side mirror (OSM) and color on encapsulation (COE) techniques to improve the disadvantage of the AOD driving and improve the power consumption of the display device.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view schematically illustrating a configuration of a display device according to a first example embodiment of the present disclosure;

FIG. 2 is a plan view schematically illustrating a display panel of FIG. 1;

FIG. 3 is a perspective view illustrating a structure in which a touch panel is embedded in a display panel;

FIG. 4 is a view illustrating a pixel structure in an AOD driving area of FIG. 2;

FIG. 5 is a cross-sectional view taken along the line I-I′ of FIG. 4;

FIG. 6 is a view illustrating a pixel structure of a normal area of FIG. 2;

FIG. 7 is a cross-sectional view taken along the line II-II' of FIG. 6;

FIG. 8 is a view illustrating a planar shape of an anode according to a first example embodiment of the present disclosure;

FIGS. 9A and 9B are views illustrating a state in which a second bank is disposed above an anode of FIG. 8;

FIG. 10 is a perspective view illustrating a pixel structure above an encapsulation unit in a display panel according to the first example embodiment of the present disclosure;

FIGS. 11A and 11B are views for explaining a self-emission mode of a display device according to the first example embodiment of the present disclosure;

FIGS. 12A and 12B are views for explaining a reflection mode of the display device according to the first example embodiment of the present disclosure;

FIGS. 13A and 13B are views for explaining a non-driving mode of the display device according to the first example embodiment of the present disclosure;

FIG. 14 is a view illustrating a pixel structure in an AOD driving area in a display device according to a second example embodiment of the present disclosure;

FIG. 15 is a cross-sectional view taken along the line III-III′ of FIG. 14;

FIGS. 16A and 16B are views for explaining a self-emission mode of the display device according to the second example embodiment of the present disclosure;

FIGS. 17A and 17B are views for explaining a reflection mode of the display device according to the second example embodiment of the present disclosure;

FIG. 18 is a view illustrating a pixel structure in an AOD driving area in a display device according to a third example embodiment of the present disclosure;

FIG. 19 is a cross-sectional view taken along the line IV-IV′ of FIG. 18;

FIG. 20 is a view illustrating a planar shape of an anode according to the third example embodiment of the present disclosure;

FIGS. 21A and 21B are views illustrating a planar shape of a bank according to the third example embodiment of the present disclosure;

FIG. 22 is a perspective view illustrating a pixel structure above an encapsulation unit in a display panel according to the third example embodiment of the present disclosure;

FIGS. 23A and 23B are views for explaining a self-emission mode of a display device according to the third example embodiment of the present disclosure;

FIGS. 24A and 24B are views for explaining a reflection mode of the display device according to the third example embodiment of the present disclosure;

FIGS. 25A and 25B are views for explaining a non-driving mode of the display device according to the third example embodiment of the present disclosure;

FIG. 26 is a view illustrating a part of a cross-section of a display panel according to a fourth example embodiment of the present disclosure; and

FIG. 27 is a view illustrating a part of a lamination structure of FIG. 26.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or other more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the drawings. All the components of each display device according to all embodiments of the present disclosure are operatively coupled and configured.

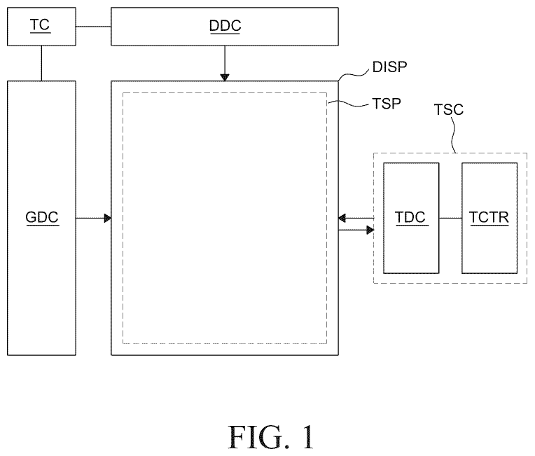

FIG. 1 is a view schematically illustrating a configuration of a display device according to a first example embodiment of the present disclosure.

For example, FIG. 1 illustrates a schematic configuration of a display device in which a touch panel TSP according to a first example embodiment of the present disclosure is embedded. However, the present disclosure is not limited thereto and a display device according to the example embodiments of the present disclosure may not include a touch panel.

Referring to FIG. 1, the display device according to the first example embodiment of the present disclosure can provide both an image displaying function and a touch sensing function.

In order to provide an image displaying function, the display device according to the first example embodiment of the present disclosure can include a display panel DISP, a gate driving circuit GDC, a data driving circuit DDC, and a timing controller TC.

For example, in the display panel DISP, a plurality of data lines and a plurality of gate lines are disposed and a plurality of sub pixels defined by the plurality of data lines and the plurality of gate lines can be disposed.

The data driving circuit DDC can drive a plurality of data lines and the gate driving circuit GDC can drive a plurality of gate lines, and the timing controller TC can control an operation of the data driving circuit DDC and the gate driving circuit GDC.

Each of the data driving circuit DDC, the gate driving circuit GDC, and the timing controller TC can be implemented by one or more individual components. In some cases, two or more of the data driving circuit DDC, the gate driving circuit GDC, and the timing controller TC can be implemented to be integrated as one component. For example, the data driving circuit DDC and the timing controller TC can be implemented as one integrated chip (IC chip).

In order to provide a touch sensing function, the display device according to the first example embodiment of the present disclosure can include a touch panel TSP and a touch sensing circuit TSC. The touch panel TSP includes a plurality of touch electrodes. The touch sensing circuit TSC supplies a touch driving signal to the touch panel TSP and detects a touch sensing signal from the touch panel TSP to sense the presence of a touch of a user or a touch position (touch coordinate) in the touch panel TSP based on the detected touch sensing signal.

For example, the touch sensing circuit TSC can include a touch driving circuit TDC, a touch controller TCTR, and the like. The touch driving circuit TDC supplies a touch driving signal to the touch panel TSP and detects a touch sensing signal from the touch panel TSP. The touch controller TCTR senses the presence of a touch of a user and/or a touch position in the touch panel TSP based on the touch sensing signal detected by the touch driving circuit TDC. The touch driving circuit TDC can include a first circuit part which supplies the touch driving signal to the touch panel TSP and a second circuit part which detects the touch sensing signal from the touch panel TSP.

For example, the touch driving circuit TDC and the touch controller TCTR can be implemented by separate components or in some cases, can be implemented to be integrated as one component.

For example, each of the data driving circuit DDC, the gate driving circuit GDC, and the touch driving circuit TDC can be implemented by one or more integrated circuits. From the viewpoint of electrical connection with the display panel DISP, the circuits can be implemented by a chip on glass (COG) type, a chip on film (COF) type, or a tape carrier package (TCP) type. Further, the gate driving circuit GDC can also be implemented by a gate in panel (GIP) type.

For example, each of circuit configurations DDC, GDC, and TC for display driving and circuit configurations TDC and TCTR for touch sensing can be implemented by one or more individual components. In some cases, one or more of the circuit configurations DDC, GDC, and TC for display driving and one or more of the circuit configurations TDC and TCTR for touch sensing are functionally integrated to be implemented by one or more components.

For example, the data driving circuit DDC and the touch driving circuit TDC can be implemented to be integrated in one or two or more integrated circuit chips. When the data driving circuit DDC and the touch driving circuit TDC are implemented to be integrated in two or more integrated circuit chips, each of two or more integrated circuit chips can have a data driving function and a touch driving function.

In the meantime, the display device according to the first example embodiment of the present disclosure can be various types such as a light emitting display device or a liquid crystal display device. Hereinafter, for the convenience of description, a light emitting display device will be described as an example of the display device. For example, even though the display panel DISP can be various types such as a light emitting display panel or a liquid crystal display panel, in the following description, for the convenience of description, a light emitting display panel will be described as an example of the display panel DISP.

Further, as it will be described below, the touch panel TSP can include a plurality of touch electrodes which is applied with a touch driving signal or detects a touch sensing signal and a plurality of touch routing lines which connects the plurality of touch electrodes to the touch driving circuit TDC.

The touch panel TSP can be provided at the outside of the display panel DISP. For example, the touch panel TSP and the display panel DISP can be separately manufactured to be combined. Such a touch panel TSP is called an external type or an add-on type.

In contrast, the touch panel TSP can be embedded in the display panel DISP. For example, when the display panel DISP is manufactured, a touch sensor structure such as a plurality of touch electrodes and a plurality of touch routing lines which configure the touch panel TSP can be formed together with a plurality of electrodes and signal lines for display driving.

Further, the touch panel TSP can be formed directly above an encapsulation unit of the display panel DISP. For example, the touch insulating film and the touch electrodes are patterned above the encapsulation unit and are connected to signal lines formed as electrodes for display driving to be driven. Hereinafter, for the convenience of description, an example that the touch panel TSP is formed directly above the encapsulation unit will be described.

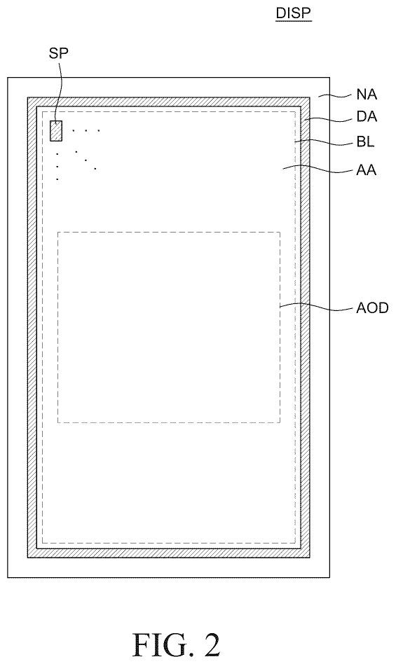

FIG. 2 is a plan view schematically illustrating a display panel of FIG. 1.

Referring to FIG. 2, the display panel DISP can include an active area AA (or display area) in which images are displayed and a non-active area NA (or non-display area) which is an outer area of an outer boundary line BL of the active area AA.

In the active area AA of the display panel DISP, a plurality of sub pixels SP for displaying images is disposed and various electrodes or signal lines for display driving are disposed.

Further, in the active area AA of the display panel DISP, a plurality of touch electrodes for touch sensing and a plurality of touch routing lines electrically connected thereto can be disposed. Accordingly, the active area AA can also be referred to as a touch sensing area which is capable of sensing the touch.

In the non-active area NA of the display panel DISP, link lines extending from various signal lines disposed in the active area AA or link lines which are electrically connected to various signal lines disposed in the active area AA, and pads which are electrically connected to the link lines can be disposed. The pads disposed in the non-active area NA can be bonded or electrically connected with the display driving circuit.

Further, in the non-active area NA of the display panel DISP, link lines extending from a plurality of touch routing lines disposed in the active area AA or link lines which are electrically connected to a plurality of touch routing lines disposed in the active area AA, and pads which are electrically connected to the link lines can be disposed. The pads disposed in the non-active area NA can be bonded or electrically connected with the touch driving circuit.

In the non-active area NA, portion that a part of an outermost touch electrode, among a plurality of touch electrodes disposed in the active area AA, extends can be disposed, or one or more electrodes (touch electrodes) formed of the same material as the plurality of touch electrodes disposed in the active area AA can be further disposed.

For example, all the plurality of touch electrodes disposed in the display panel DISP can be disposed in the active area AA or some (for example, an outermost touch electrode) among the plurality of touch electrodes disposed in the display panel DISP can be disposed in the non-active area NA. Some (for example, an outermost touch electrode) among the plurality of touch electrodes disposed in the display panel DISP can be disposed in both the active area AA and the non-active area NA.

In the meantime, referring to FIG. 2, the display panel DISP according to the first example embodiment of the present disclosure can include a dam area DA having a dam for suppressing any layer (for example, the encapsulation unit in the display panel) in the active area AA from passing over to the outside of the display panel DISP.

The dam area DA can be located at a boundary of the active area AA and the non-active area NA or at any one position of a non-active area NA which is an outer area of the active area AA.

A dam disposed in the dam area DA can be disposed to enclose all directions of the active area AA or disposed only at an outside of one or two or more parts of the active area AA.

The dam disposed in the dam area DA can have one pattern which is connected or two or more separated patterns. Further, in the dam area DA, only a primary dam can be disposed or two dams (primary dam and secondary dam) can be disposed, or three or more dams can also be disposed.

For example, in the dam area DA, in any one direction, only the primary dam is disposed and in the other direction, both the primary dam and the secondary dam can be disposed.

In the meantime, the display panel DISP of the first example embodiment of the present disclosure can include an always-on-display (AOD) driving area AOD which always drives a part of the active area AA to transmit information even in a turned-off state of the display device. The AOD driving area AOD can include a status bar area which displays a state of the display device.

For example, when the AOD is displayed on the active area AA, sub pixels SP in the AOD driving area AOD are activated, but sub pixels in areas other than the AOD driving area AOD are inactivated. Accordingly, when the AOD is displayed on the active area AA, only sub pixels in the AOD driving area AOD can be driven.

Further, for example, the display panel (DISP) driving circuit can drive only sub pixel SP of the AOD driving area AOD in the AOD driving mode under the control of the timing controller (TC in FIG. 1) to display data of predetermined AOD information on the sub pixels SP of the AOD driving area AOD. Accordingly, in the AOD driving mode, only the sub pixels SP of the AOD driving area AOD are activated and the sub pixels SP in an area other than the AOD driving area AOD are not driven to be inactivated.

The display device of the present disclosure can be applied to a mobile information terminal. The mobile information terminal includes a portable phone, a smart phone, a tablet computer, a notebook computer, a wearable device, and the like. The mobile information terminal stops the driving of the display device to reduce power consumption, thereby reducing power consumption in a standby mode (or a sleep mode) or a locked state. However, a user restarts the mobile information terminal to see simple information, like a watch, to frequently and repeatedly turn on/off the mobile information terminal so that the user can feel inconvenience. In order to reduce the user's inconvenience, an AOD function which drives only pixels in a partial area of the screen in the standby mode or the locked state to display information such as date or watch is set in the mobile information terminal. When the AOD function is activated, the mobile information terminal does not drive the entire screen, but drives (partially displays) only some pixels on the screen to always display simple AOD information such as date or watch. If the AOD information is always displayed on pixels in the same position, the pixels are degraded faster than the other pixels, which causes the afterimage. In order to improve this problem, according to the present disclosure, increased reflected light is utilized as a reflection mode in the ADO driving area ADO by applying OLED side mirror (OSM) and color on encapsulation (COE) techniques to suppress the degradation of pixels and improve the power consumption of the display device.

Even though in FIG. 2, it is illustrated that the AOD driving area AOD is disposed in the center of the active area AA for the sake of convenience, the present disclosure is not limited thereto and the AOD driving area AOD can be freely disposed on an upper end or a lower end of the active area AA.

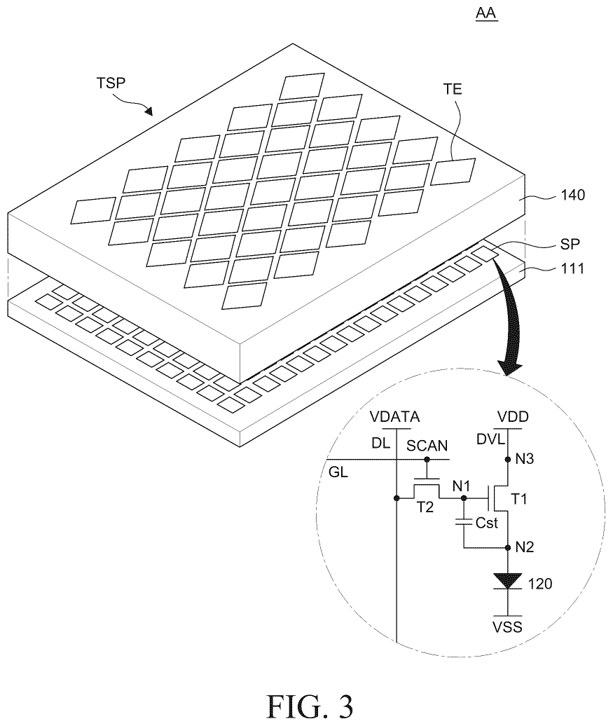

FIG. 3 is a perspective view illustrating a structure in which a touch panel is embedded in a display panel. Particularly, FIG. 3 is a perspective view illustrating a structure in which the touch panel is embedded in the display panel according to the first example embodiment of the present disclosure.

Referring to FIG. 3, for example, in the active area AA of the display panel (DISP in FIG. 2), a plurality of sub pixels SP can be disposed above the substrate 111.

Each sub pixel SP can include a light emitting diode 120, a first transistor T1 for driving the light emitting diode 120, a second transistor T2 for transmitting a data voltage VDATA to a first node N1 of the first transistor T1, and a storage capacitor Cst for maintaining a constant voltage for one frame.

For example, the first transistor T1 can include a first node N1 to which the data voltage VDATA is applied, a second node N2 which is electrically connected to the light emitting diode 120, and a third node N3 to which a driving voltage VDD is applied from a driving voltage line DVL. The first node N1 can be a gate node, the second node N2 can be a source node or a drain node, and the third node N3 can be a drain node or a source node. The first transistor T1 can also be referred to as a driving transistor which drives the light emitting diode 120.

The light emitting diode 120 can include a first electrode (for example, an anode), an emission layer, and a second electrode (for example, a cathode). The first electrode is electrically connected to the second node N2 of the first transistor T1 and the second electrode can be applied with a base voltage VSS.

The emission layer in the light emitting diode 120 can be an emission layer including an organic material or an inorganic material.

For example, the second transistor T2 is controlled to be turned on or off by a scan signal SCAN applied through the gate line GL and can be electrically connected between the first node N1 of the first transistor T1 and the data line DL. Further, the second transistor T2 can be referred to as a switching transistor.

For example, when the second transistor T2 is turned on by the scan signal SCAN, the second transistor T2 can transmit the data voltage VDATA supplied from the data line DL to the first node N1 of the first transistor T1.

The storage capacitor Cst can be electrically connected between the first node N1 and the second node N2 of the first transistor T1.

As illustrated in FIG. 3, each sub pixel SP can have a 2T1C structure including two transistors T1 and T2 and one capacitor Cst and in some cases, can further include one or more transistors or further include one or more capacitors.

The storage capacitor Cst is not a parasitic capacitor (for example, Cgs or Cgd) which is an internal capacitor present between the first node N1 and the second node N2 of the first transistor T1, but can be an external capacitor which is intentionally designed at the outside of the first transistor T1.

The first transistor T1 and the second transistor T2 can be configured by an n-type transistor or a p-type transistor. As described above, in the display panel DISP, circuit elements such as a light emitting diode 120, two or more transistors T1 and T2, and one or more capacitors Cst can be disposed. The circuit element (specifically, the light emitting diode 120) is vulnerable to external moisture or oxygen so that an encapsulation unit 140 for suppressing the external moisture or oxygen from permeating the circuit element can be disposed on the display panel DISP.

The encapsulation unit 140 can be formed by one layer, or also formed by a plurality of layers.

In the meantime, in the display device according to the first example embodiment of the present disclosure, the touch panel TSP can be disposed above the encapsulation unit 140. For example, in the display device according to the first example embodiment of the present disclosure, a touch sensor structure, such as a plurality of touch electrodes TE which configures a touch panel TSP, can be disposed above the encapsulation unit 140.

During the touch sensing, a touch driving signal or a touch sensing signal can be applied to the touch electrode TE. Accordingly, during the touch sensing, a potential difference is formed between the touch electrode TE and the cathode which are disposed with the encapsulation unit 140 therebetween so that an unnecessary parasitic capacitance can be formed. At this time, the parasitic capacitance can degrade a touch sensitivity. Therefore, in order to lower the parasitic capacitance, a distance between the touch electrode TE and the cathode can be designed to be larger than a predetermined value (for example, 1 μm) in consideration of a thickness of the display panel DISP, a display panel (DISP) manufacturing process, a display performance, and the like. To this end, for example, the thickness of the encapsulation unit 140 can be designed to be at least 1 μm or larger.

In the meantime, the display device according to the first example embodiment of the present disclosure can sense the touch based on capacitance formed in the touch electrode TE.

The display device according to the first example embodiment of the present disclosure employs a capacitance-based touch sensing manner so that the touch can be sensed by a mutual-capacitance-based touch sensing manner or a self-capacitance-based touch sensing manner.

For example, according to the mutual-capacitance-based touch sensing manner, a plurality of touch electrodes TE can be classified into a driving touch electrode (a transmission touch electrode) to which a touch driving signal is applied and a sensing touch electrode (a reception touch electrode) which detects a touch sensing signal and forms a capacitance with the driving touch electrode.

In the case of the mutual-capacitance-based touch sensing manner, the touch sensing circuit can sense the presence of the touch and/or the touch coordinate, etc., based on the change in capacitance (mutual-capacitance) between the driving touch electrode and the sensing touch electrode depending on the presence of a pointer such as a finger or a pen.

According to the self-capacitance-based touch sensing manner, each touch electrode TE can serve as both a driving touch electrode and a sensing touch electrode. For example, the touch sensing circuit applies a touch driving signal to one or more touch electrodes TE and detects a touch sensing signal by means of the touch electrode TE applied with the touch driving signal. The touch sensing circuit identifies the change in capacitance between a pointer such as a finger or a pen and the touch electrode TE based on the detected touch sensing signal to sense the presence of touch and/or the touch coordinate, etc. In the self-capacitance-based touch sensing manner, the driving touch electrode and the sensing touch electrode are not distinguished.

As described above, the display device according to the first example embodiment of the present disclosure can sense the touch by the mutual-capacitance-based touch sensing manner or the self-capacitance-based touch sensing manner. However, in the following description, for the convenience of description, it will be described that the display device performs mutual-capacitance-based touch sensing and includes a touch sensor structure therefor, as an example.

Hereinafter, a configuration of a sub pixel according to one or more embodiments of the present disclosure will be described in detail with reference to the drawing.

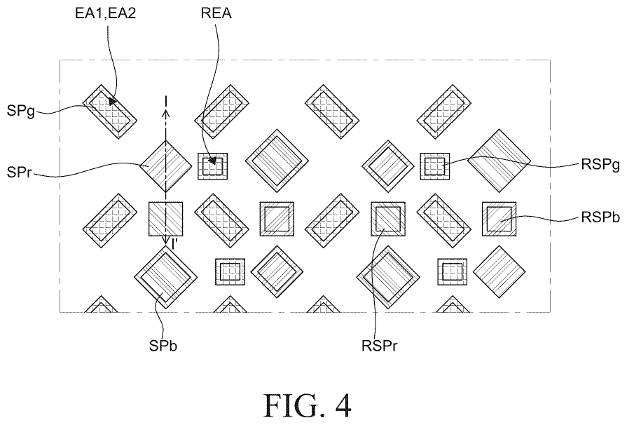

FIG. 4 is a view illustrating a pixel structure in an AOD driving area of FIG. 2.

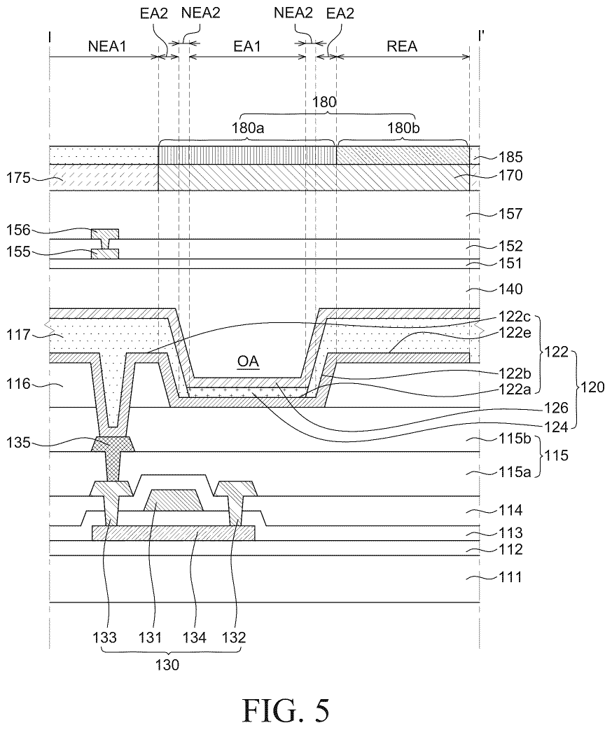

FIG. 5 is a cross-sectional view taken along the line I-I′ of FIG. 4.

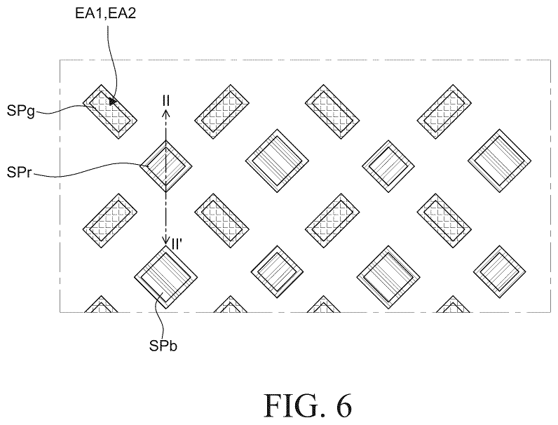

FIG. 6 is a view illustrating a pixel structure of a normal area of FIG. 2.

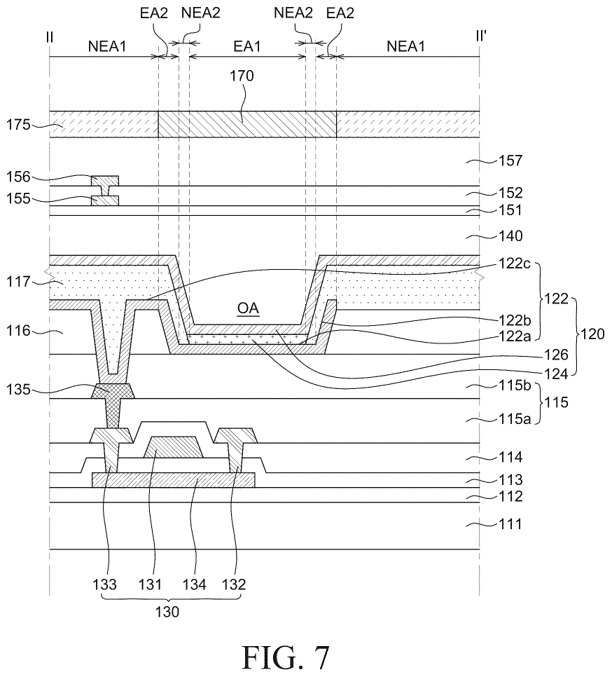

FIG. 7 is a cross-sectional view taken along the line II-II′ of FIG. 6.

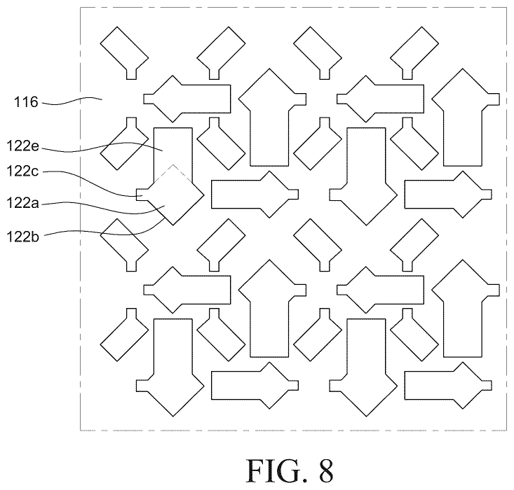

FIG. 8 is a view illustrating a planar shape of an anode according to the first example embodiment of the present disclosure.

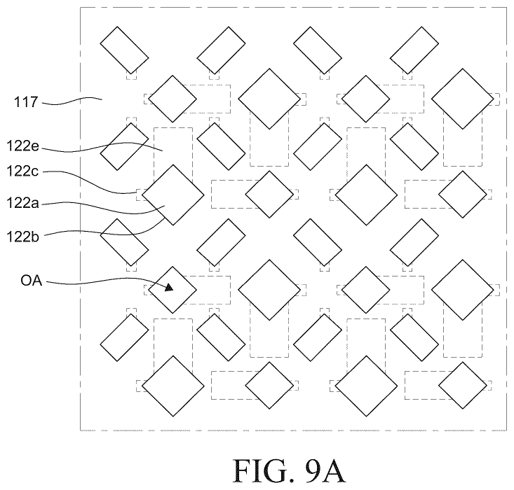

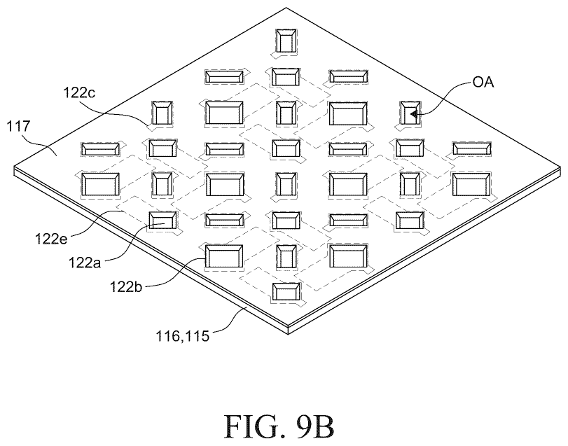

FIGS. 9A and 9B are views illustrating a state in which a second bank is disposed above an anode of FIG. 8.

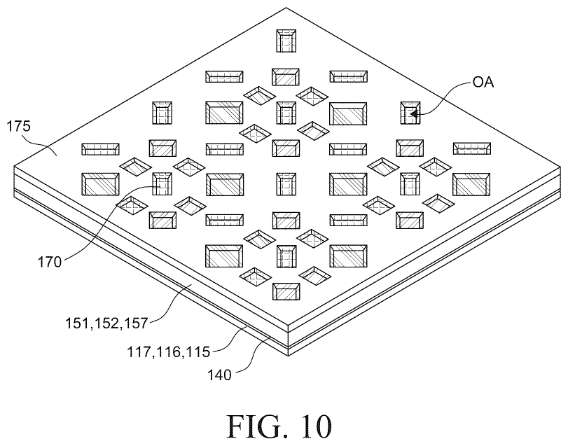

FIG. 10 is a perspective view illustrating a pixel structure above an encapsulation unit in a display panel according to the first example embodiment of the present disclosure.

For example, FIGS. 4 and 5 illustrate a pixel structure and a part of a cross-sectional structure of one sub pixel, in the AOD driving area (AOD in FIG. 2).

Further, for example, FIGS. 6 and 7 illustrate a pixel structure and a part of a cross-sectional structure of one sub pixel, in a normal area.

For the convenience of description, in FIGS. 4 and 6, sub pixels SPr, SPg, and SPb are defined with respect to an anode which forms an emission area, but it is not limited thereto. Here, the emission area can correspond to the sub pixels SPr, SPg, and SPb, but is not limited thereto. In the meantime, in the AOD driving area AOD of FIG. 4, as compared with the normal area of FIG. 6, sub pixels RSPr, RSPg, and RSPb of a reflection area can be added in addition to the sub pixels SPr, SPg, and SPb.

FIG. 9A is a plan view illustrating an example that a second bank 117 is disposed above the anode 122 of FIG. 8 and FIG. 9B is a perspective view of FIG. 9A.

FIG. 10 illustrates an example that an encapsulation unit 140, a touch buffer film 151, a touch insulating film 152, a touch planarization film 157, a color filter layer 170, and a black matrix 175 are sequentially disposed above the second bank 117 of FIGS. 9A and 9B.

Referring to FIGS. 4 and 6, the display panel of the first example embodiment of the present disclosure can include a plurality of pixels configured by a first sub pixel SPr, a second sub pixel SPg, and a third sub pixel SPb.

The first sub pixel SPr, the second sub pixel SPg, and the third sub pixel SPb have different shapes, but have substantially same configuration.

For example, the first sub pixel SPr can be a red sub pixel. For example, the second sub pixel SPg can be a green sub pixel. For example, the third sub pixel SPb can be a blue sub pixel.

For example, the first sub pixels SPr and the third sub pixel SPb can have an approximately square shape, but the present disclosure is not limited thereto.

For example, the second sub pixel SPg can have an approximately rectangular shape, but is not limited thereto.

For example, one pixel can be configured by one first sub pixel SPr, two second sub pixels SPg, and one third sub pixel SPb, but is not limited thereto.

Here, the shape of the sub pixels SPr, SPg, and SPb can be defined by a shape of a first area (122a in FIGS. 5 and 7) of the anode (122 in FIGS. 5 and 7), but is not limited thereto.

In the meantime, in the first example embodiment of the present disclosure, the anode 122 has a side mirror (SM) structure so that a reflective emission area (EA2 of FIGS. 5 and 7) is added in addition to a main emission area (EA1 in FIGS. 5 and 7) so that each emission area can extend as compared with the sub pixels SPr, SPg, and SPb.

Further, according to the first example embodiment of the present disclosure, in the AOD driving area AOD, the anode 122 has an extending area (122e of FIG. 5) extending in one direction so that a reflection area can be added in addition to the emission area. Here, shapes of the sub pixels RSPr, RSPg, and RSPb of the reflection area can be defined by the shape of the extending area 122e of the anode 122, but the present disclosure is not limited thereto.

For example, the sub pixels RSPr, RSPg, and RSPb of the reflection area can have different shapes and have the substantially same configuration. The sub pixels RSPr, RSPg, and RSPb of the reflection area are defined for the convenience of description and can actually refer to areas which are adjacent to the sub pixels SPr, SPg, and SPb to extend from the sub pixels SPr, SPg, and SPb.

For example, the first sub pixel RSPr of the reflection area is disposed between the first sub pixel SPr and the third sub pixel SPb and can extend from the first sub pixel SPr.

For example, the second sub pixel RSPg of the reflection area is disposed between the second sub pixels SPg and can extend from the second sub pixel SPg.

For example, the third sub pixel RSPb of the reflection area is disposed between the first sub pixel SPr and the third sub pixel SPb and can extend from the third sub pixel SPb.

For example, the first sub pixel RSPr of the reflection area, the second sub pixel RSPg of the reflection area, and the third sub pixel RSPb of the reflection area can have an approximately square shape, but are not limited thereto and can have an approximately rectangular shape.

Referring to FIGS. 5 and 7, a buffer layer 112, such as a multi-buffer layer or a lower buffer layer, can be disposed above the substrate 111.

Recently, the flexible substrate 111 can use a ductile material having a flexible characteristic such as plastic.

The substrate 111 can be a film type including one of a group consisting of a polyester-based polymer, a silicon-based polymer, an acrylic polymer, a polyolefin-based polymer, and a copolymer thereof.

The substrate 111 can include a first substrate, a second substrate, and an insulating film. The insulating film can be disposed between the first substrate and the second substrate. As described above, the substrate 111 is configured by the first substrate, the second substrate, and the insulating film to suppress the moisture permeation. For example, the first substrate and the second substrate can be polyimide (PI) substrates.

For example, the multi-buffer layer can delay the spreading of the moisture or oxygen permeating the substrate 111 and can be formed by alternately laminating silicon nitride (SiNx) and silicon oxide (SiOx) at least once.

For example, the lower buffer layer can perform a function of protecting the semiconductor layer 134 and blocking various types of defects entering from the substrate 111.

For example, the lower buffer layer can be formed by amorphous silicon, silicon nitride (SiNx), silicon oxide (SiOx), or the like.

The switching thin film transistor (T2 in the pixel driving circuit of FIG. 3) and the driving thin film transistor 130 (T1 in the pixel driving circuit of FIG. 3) can be disposed above the buffer layer 112.

Specifically, the semiconductor layer 134 can be disposed in the active area above the substrate 111.

For example, the semiconductor layer 134 can be formed of a polycrystalline semiconductor and can include a channel region, a source region, and a drain region. However, it is not limited thereto and the semiconductor layer 134 can be configured by amorphous silicon or oxide semiconductor.

The gate insulating film 113 can be disposed on the semiconductor layer 134.

The gate insulating film 113 can be configured by a single layer of silicon nitride (SiNx) or silicon oxide (SiOx) or a multilayer thereof.

A gate line can be disposed in a first direction and a gate electrode 131 which is connected to the gate line can be disposed, on the gate insulating film 113.

The gate electrode 131 can be disposed on the gate insulating film 113 so as to overlap the semiconductor layer 134.

For example, the gate electrode 131 and the gate line can be configured by a single layer or multiple layers of copper (Cu), aluminum (Al), molybdenum (Mo), chrome (Cr), gold (Au), titanium (Ti), nickel (Ni), and neodymium (Nd) which are conductive metals or an alloy thereof, but the present disclosure is not limited thereto.

An interlayer insulating film 114 can be disposed on the gate electrode 131 so as to cover the gate electrode 131.

For example, the interlayer insulating film 114 can be configured by a single layer of silicon nitride (SiNx) or silicon oxide (SiOx) or a multilayer thereof.

At this time, a partial area of the interlayer insulating film 114 and the gate insulating film 113 is selectively removed to form a contact hole which exposes both ends of the semiconductor layer 134.

The data line can be disposed on the interlayer insulating film 114 in a second direction intersecting the gate line.

Further, a source electrode 132 and a drain electrode 133 which are connected to both ends of the semiconductor layer 134, respectively, can be disposed on the interlayer insulating film 114.

A protective film can be disposed on the data line and the source electrode 132 and the drain electrode 133. The protective film can be omitted as needed.

The protective film can be formed as a single layer of silicon nitride (SiNx) or silicon oxide (SiOx) or a multilayer thereof.

A planarization film 115 can be disposed on the protective film. The planarization film 115 can have a multi-layered structure configured by at least two layers and for example, can include a first planarization film 115a and a second planarization film 115b. The first planarization film 115a can be disposed to cover the driving thin film transistor 130 and expose a part of the drain electrode 133 of the driving thin film transistor 130.

A thickness of the planarization film 115 can be approximately 2 μm, but is not limited thereto.

The planarization film 115 can be an overcoat layer, but is not limited thereto.

For example, the connection electrode 135 can be disposed on the first planarization film 115a to electrically connect the driving thin film transistor 130 and the light emitting diode 120. Further, referring to FIGS. 5 and 7, various metal layers which serve as wiring lines/electrodes, such as a data line or a signal line, can be disposed on the first planarization film 115a.

The connection electrode 135 can be configured with a material, such as copper (Cu), aluminum (Al), molybdenum (Mo), chrome (Cr), gold (Au), titanium (Ti), nickel (Ni), and neodymium (Nd), or an alloy thereof.

Further, the second planarization film 115b can be disposed on the first planarization film 115a and the connection electrode 135.

For example, since various signal lines are increased in accordance with the increased resolution of the display panel, the planarization film 115 is formed by two layers in the display panel according to the first example embodiment of the present disclosure. Therefore, it is difficult to dispose all the wiring lines on one layer while ensuring a minimum interval so that an additional layer is provided. Such an additional layer, for example, the second planarization film 115b is added so that there is a margin for disposing wiring lines, which makes it easier to design and dispose the wiring lines/electrodes. Further, when a dielectric material is used for the planarization film 115 configured by a plurality of layers, the planarization film 115 can be utilized to form a capacitance between metal layers.

The second planarization film 115b can be formed to expose a part of the connection electrode 135 and the drain electrode 133 of the driving thin film transistor 130 and the anode 122 of the light emitting diode 120 can be electrically connected by the connection electrode 135.

The planarization film 115 can be configured with one or more materials of acrylic resin, epoxy resin, phenolic resin, polyamides resin, polyimides resin, unsaturated polyesters resin, polyphenylene resin, benzocyclobutene, and polyphenylenesulfides resin, but is not limited thereto.

The first bank 116 can be disposed on the second planarization film 115b.

For example, the first bank 116 can be disposed in a first non-emission area NEA1 and a reflection area REA of the substrate 111 on the second planarization film 115b. At this time, in the pixel of the normal area of FIG. 7, the reflection area REA is not provided so that the first bank 116 can be disposed in a first non-emission area NEA1 of the substrate 111 on the second planarization film 115b. For example, the first non-emission area NEA1 and the reflection area REA can be disposed around the main emission area EA1.

For example, the first non-emission area NEA1 can be located so as to correspond to the first bank 116 in which the second area 122b of the anode 122 and the extending area 122e are not located. Further, a second non-emission area NEA2 can be located between the main emission area EA1 and the reflective emission area EA2.

The first bank 116 can be formed of an organic material. For example, the first bank 116 can be formed of polyimide, acrylic, or benzocyclobutene resin, but is not limited thereto.

Further, the first bank 116 can be formed of a black material. For example, the first bank 116 can be configured such that the black pigment is dispersed in an organic material, but is not limited thereto and as long as the first bank has a black color, the first bank can be configured by an arbitrary black material. For example, the organic material can be cardo-based polymer and polymer including epoxy acrylate, but is not limited thereto. As the first bank 116 includes the black material, the first bank 116 can reduce external light reflection, specifically, scattered reflection which can be generated by a transparent second bank 117. For example, in order to reduce the reflection of external light, an optical density of the first bank 116 can be configured to be 4 or lower at the thickness of 3 μm of the first bank 116, but is not limited thereto. Further, in order to reduce the reflection of the external light, the reflectance of the first bank 116 can be 1% or lower, but is not limited thereto.

The light emitting diode 120 which is electrically connected to the connection electrode 135 through a contact hole can be disposed above the second planarization film 115b in which the first bank 116 is not disposed.

At this time, for example, the light emitting diode 120 can include an anode 122 connected to the drain electrode 133 of the driving thin film transistor 130, a plurality of organic layers 124 disposed on the anode 122, and a cathode 126 disposed on the organic layers 124. The organic layer 124 can be referred to as a light emitting unit, but is not limited to the term.

Further, for example, the anode 122 can include a first area 122a which is disposed on the second planarization film 115b to be in contact with the second planarization film 115b and a second area 112b which extends from the first area 122a to be disposed on the side surface of the first bank 116. The first area 112a has a surface substantially parallel to a surface of the substrate 111 and the second area 112b has a surface which has a predetermined angle with respect to the substrate 111. Accordingly, the surface of the second area 122b may not be parallel to the surface of the substrate 111.

Further, for example, the anode 122 can include a third area 122c which extends from the second area 122b in one direction to be electrically connected to the connection electrode 135 through a contact hole.

Further, the anode 122 can include an extending area 122e which extends from the second area 122b in the other direction to be in contact with the top surface of the first bank 116 and has a surface substantially parallel to a surface of the substrate 111. The extending area 122e can correspond to the reflection area REA.

Referring to FIG. 8, for example, the first area 122a can have an approximately square shape and the extending area 122e extends from the first area 122a to have an approximately rectangular shape. The second area 122b can be an inclined side surface in the vicinity of the first area 122a and the third area 122c extends from the second area 122b in one direction to be electrically connected to the connection electrode 135 through a contact hole.

The anode 122 can be electrically connected to the source electrode 132 or the drain electrode 133 of the driving thin film transistor 130.

The anode 122 can include a reflective layer which is formed of a reflective metal.

Even though in FIGS. 5 and 7, for the convenience of description, an example that the anode 122 is configured as a single layer is illustrated, the present disclosure is not limited thereto and the anode 122 can be configured with a multi-layered structure. When the anode 122 is configured with the multi-layered structure, at least one layer can include a reflective metal.

For example, the anode 122 can have a multi-layered structure including a transparent layer configured by a transparent conductive film and a reflective layer configured by an opaque conductive film having a high reflection efficiency. For example, the transparent conductive film can be configured with a material having a relatively high work function, such as indium-tin-oxide (ITO) or indium-zinc-oxide (IZO) and the opaque conductive film can be configured with a single or multi-layered structure including copper (Cu), silver (Ag), aluminum (Al), molybdenum (Mo), titanium (Ti), or an alloy thereof. For example, the anode 122 can be configured by a structure in which a transparent conductive film, an opaque conductive film, and a transparent conductive film are sequentially laminated or can be configured by a structure in which a transparent conductive film and an opaque conductive film are sequentially laminated.

In the meantime, the second area 122b of the anode 122 of the present disclosure can be disposed on the side surface of the first bank 116 along a shape of the side surface of the first bank 116. The second area 122b of the anode 122 disposed on the side surface of the first bank 116 can have a taper angle of approximately 30° to 60°, but is not limited thereto. The second area 122b of the anode 122 including the reflective layer can serve as a side mirror SM. Accordingly, the emission area according to the first example embodiment of the present disclosure can further include the reflective emission area EA2 by the SM structure, in addition to the main emission area EA1. The reflective emission area EA2 can be formed between the main emission area EA1 and the first non-emission area NEA1 and between the main emission area EA1 and the reflection area REA so as to correspond to the second area 122b of the anode 122.

When the display device according to the first example embodiment of the present disclosure is a top emission type light emitting display device, the reflective layer of the anode 122 can upwardly reflect the light emitted from the light emitting diode 120. The light generated in the organic layer 124 of the light emitting diode 120 can be emitted not only upwardly, but also laterally. The laterally emitted light can be directed into the display device, or trapped in the display device by the total reflection, or travel into the display device and then dissipate. Therefore, according to the present disclosure, the second area 122b of the anode 122 including the reflective layer is disposed on the side surface of the first bank 116 to change a traveling direction of light which laterally travels to an upward direction. Therefore, the light extraction efficiency of the display device can be improved.

According to the first example embodiment of the present disclosure, a reflection area REA can be further included in addition to the emission area in the AOD driving area AOD. For example, the reflection area REA corresponds to the extending area 122e of the anode 122 to be formed between the reflective emission area EA2 and a first non-emission area NEA1 of an adjacent sub pixel.

For example, the second bank 117 can be disposed above the first bank 116 and the anode 122 while covering a part of the anode 122.

For example, the second bank 117 can cover a part of the first area 122a, the second area 122b, the third area 122c, and the extending area 122e of the anode 122. The second bank 117 can cover a part of an edge of the first area 122a. Further, the second bank 117 can cover the entire second area 122b, the entire third area 122c, and the entire extending area 122e (see FIGS. 9A and 9B).

A part of the second bank 117 corresponding to the main emission area EA1 can be open.

For example, the second bank 117 can include an open area OA obtained by removing (opening) a part corresponding to the main emission area EA1 of a sub pixel (see FIGS. 9A and 9B).

The second bank 117 can include a top surface, a side portion, and a bottom surface.

The top surface of the second bank 117 is a surface located at the top of the second bank 117 and can be substantially parallel to the substrate 111. Further, the top surface of the second bank 117 can correspond to the top surface of the first bank 116.

The side portion of the second bank 117 can be a surface extending from the top surface of the second bank 117 to a side surface. The side portion of the second bank 117 can have a predetermined taper angle. For example, a side portion of the second bank 117 can have a taper angle of 30° to 65°, but is not limited thereto. The side portion of the second bank 117 can correspond to the side surface of the first bank 116.

Next, the bottom surface of the second bank 117 can correspond to a surface which abuts the anode 122 in the first area 122a of the anode 122. At this time, the bottom surface of the second bank 117 can correspond to a second non-emission area NEA2 between the main emission area EA1 and the reflective emission area EA2. Next, a bottom surface of the second bank 117 can include a surface which abuts the anode 122 in the second area 122b and the third area 122c of the anode 122. In the meantime, in the AOD driving area AOD, a bottom surface of the second bank 117 can include a surface which abuts the anode 122 in the second area 122b, the third area 122c, and the extending area 122e of the anode 122.

As described above, the sub pixel in the normal area according to the first example embodiment of the present disclosure can have a plurality of emission areas EA1 and EA2 and a plurality of non-emission areas NEA1 and NEA2. Further, the sub pixel in the AOD driving area AOD according to the first example embodiment of the present disclosure can have a plurality of emission areas EA1 and EA2, a plurality of non-emission areas NEA1 and NEA2, and a reflection area REA.

In each sub pixel, the main emission area EA1 can have a larger width than the reflective emission area EA2. In each sub pixel, the first non-emission area NEA1 can have a larger width than the second non-emission area NEA2, but it is not limited thereto.

For example, the second non-emission area NEA2 can be located between the main emission area EA1 and the reflective emission area EA2.

In each sub pixel, the reflective emission area EA2 can be disposed in the vicinity of the main emission area EA1 and the reflection area REA can be extended and disposed from the main emission area EA1 between the main emission areas EA1 of adjacent sub pixels.

The second bank 117 can be formed of an organic material. For example, the second bank 117 can be formed of polyimide, acrylic, or benzocyclobutene resin, but is not limited thereto.

Further, the second bank 117 can be formed of a transparent material, but is not limited thereto.

In FIGS. 5 and 7, for the convenience of description, it is illustrated that an organic layer 124 which is represented as an emission layer is disposed only in the open area OA, but it is not limited thereto. The organic layer 124 can also be disposed on the top surface and a side portion of the second bank 117 including the open area OA of the second bank 117.

For example, the organic layer 124 can include a hole injection layer, a hole transport layer, an emission layer, an electron transport layer, and an electron injection layer. In a tandem structure in which a plurality of emission layers is overlaid, a charge generation layer can be further disposed between the emission layers. The emission layer can emit different color light in every sub pixel. For example, a red emission layer, a green emission layer, and a blue emission layer can be separately disposed in every sub pixel, but the present disclosure is not limited thereto. However, a common emission layer is formed in every sub pixel to emit white light without distinguishing the color and a color filter which distinguishes the color can be separately provided. In this case, the emission layer can be individually disposed, but the hole injection layer, the electron injection layer, the hole transport layer, or the electron transport layer is provided as a common layer to be disposed in each sub pixel in the same way.

Further, the cathode 126 can be disposed on the organic layer 124 so as to be opposite to the anode 122 with the organic layer 124 therebetween. For example, when the cathode 126 is applied to a top emission type display device, the cathode can be configured by a transparent conductive film obtained by forming indium tin oxide (ITO), indium zinc oxide (IZO), or magnesium-silver (Mg—Ag) to be thin.

The encapsulation unit 140 can be disposed above the cathode 126 to protect the light emitting diode 120.

The light emitting diode 120 can react to external moisture and oxygen due to a characteristic of the organic material of the organic layer 124 to cause dark-spot or pixel shrinkage. In order to suppress this problem, the encapsulation unit 140 can be disposed above the cathode 126. The encapsulation unit 140 can be configured by a first inorganic insulating film, a foreign material compensation layer, and a second inorganic insulating film, but is not limited thereto.

The first inorganic insulating film can be disposed above the substrate 111 in which the cathode 126 is disposed to be the most adjacent to the light emitting diode 120.

For example, the first inorganic insulating film can be configured by an inorganic insulating material on which low-temperature deposition is allowed, such as silicon nitride (SiNx), silicon oxide (SiOx), silicon oxynitride (SiON), or aluminum oxide (Al₂O₃). The first inorganic insulating film is deposited under a low temperature atmosphere so that the damage of the organic layer 124 including an organic material vulnerable to the high temperature atmosphere during the deposition can be suppressed.

A foreign material compensation layer can be disposed to have a smaller area than the first inorganic insulating film and can be configured to expose both ends of the first inorganic insulating film. The foreign material compensation layer can be formed of an organic insulating material, such as acrylic resin, epoxy resin, polyimide, polyethylene, or silicon oxy carbon (SiOC).

In the meantime, when the foreign material compensation layer is formed by an inkjet method, one or more dams can be disposed in a boundary area of the non-active area and the active area or a dam area corresponding to a partial area in the non-active area. In such a dam area, a primary dam adjacent to the active area and a secondary dam adjacent to the pad unit can be disposed.

When a liquid type foreign material compensation layer is dropped in the active area, one or more dams disposed in the dam area can suppress the liquid type foreign material compensation layer from collapsing in the direction of the non-active area to invade the pad unit. The primary dam and/or secondary dam can be configured as a single layer or a

multi-layered structure. For example, the primary dam and/or secondary dam can be simultaneously configured with the same material as at least one of the planarization film 115, the first bank 116, the second bank 117, and the spacer. In this case, the dam structure can be configured without having the mask adding process and increasing the cost.

Further, the foreign material compensation layer including an organic material can be located only on an inner surface of the primary dam.

Further, the second inorganic insulating film can be disposed so as to cover an upper surface and a side surface of each of the first inorganic insulating film and the foreign material compensation layer. The second inorganic insulating film can serve to minimize or block the permeation of the external moisture or oxygen into the first inorganic insulating film and the foreign material compensation layer. The second inorganic insulating film can be formed of an inorganic insulating material, such as silicon nitride (SiNx), silicon oxide (SiOx), silicon oxynitride (SiON), or aluminum oxide (Al₂O₃).

A touch buffer film 151 can be disposed on the encapsulation unit 140.

A bridge pattern 155 can be disposed on the touch buffer film 151. However, it is not limited thereto and a touch electrode (or a touch routing line) can be disposed on the touch buffer film 151.

The touch buffer film 151 can be located between the bridge pattern 155 and the encapsulation unit 140.

For example, the touch buffer film 151 can be designed to maintain a predetermined minimum interval between the bridge pattern 155 and the cathode 126. By doing this, a parasitic capacitance which can be formed between the bridge pattern 155 and the cathode 126 can be reduced or suppressed so that degradation of the touch sensitivity due to the parasitic capacitance can also be suppressed.

The bridge pattern 155 can be disposed above the encapsulation unit 140 without having the touch buffer film 151.

The bridge pattern 155 can have a single or multi-layered structure formed of a metal having strong corrosion resistance and acid resistance, such as aluminum (Al), titanium (Ti), copper (Cu), or molybdenum (Mo).

The touch insulating film 152 can be disposed on the bridge pattern 155.

For example, the touch insulating film 152 can use an organic film or an inorganic film which can be formed by a low temperature process. When the organic film is used for the touch insulating film 152, after coating the organic film above the substrate 111, the organic film is cured at a temperature of 100° C. or lower to form the touch insulating film 152 to suppress the damage of the organic layer 124 vulnerable to the high temperature. When the inorganic film is used for the touch insulating film 152, in order to suppress the damage of the organic layer 124 vulnerable to the high temperature, a low temperature chemical vapor deposition (CVD) process and a washing process are repeated at least twice to form the touch insulating film 152 with a multi-layered structure.

A partial area of the touch insulating film 152 is selectively removed to form a touch contact hole to expose a part of the bridge pattern 155.

A touch electrode (or a touch routing line) 156 can be disposed on the touch insulating film 152. However, it is not limited thereto and the bridge pattern can be disposed on the touch insulating film 152.

For example, the touch electrode 156 can be electrically connected to the bridge pattern 155 through the touch contact hole.

Further, the touch planarization film 157 can be disposed on the touch electrode 156, but is not limited thereto and the touch planarization film can be omitted.

The black matrix 175 can be disposed on the touch planarization film 157 (see FIG. 10). The black matrix 175 can be located above the touch electrode 156. The black matrix 175 can be located so as to correspond to the first non-emission area NEA1.

The color filter layer 170 can be disposed in the emission areas EA1 and EA2, the second non-emission area NEA2, and the reflection area REA between the black matrixes 175 (see FIG. 5 and FIG. 10).

For example, the color filter layer 170 can include a red color filter layer, a green color filter layer, and a blue color filter layer, but is not limited thereto and can further include a white color filter layer.

The black matrix 175 can be disposed on the boundary of color filter layers 170 with different colors. Therefore, the black matrix 175 can define a sub pixel area. Sub pixel areas defined by the black matrix 175 can be a red sub pixel area, a green sub pixel area, and a blue sub pixel area. Further, the sub pixel area can further include a white sub pixel area. For example, an area in which the red color filter layer is disposed can correspond to a red sub pixel area, an area in which the green color filter layer is disposed can correspond to a green sub pixel area, an area in which a blue color filter layer is disposed can correspond to a blue sub pixel area. Further, an area in which a white color filter layer is disposed can correspond to a white sub pixel area.

For example, in the area in which the red color filter layer is disposed, red light can be emitted, in the area in which the green color filter layer is disposed, green light can be emitted, in the area in which the blue color filter layer is disposed, blue light can be emitted, and in the area in which the white color filter layer is disposed, white light can be emitted.

In the meantime, as described above, according to the present disclosure, the anode 122 has a side mirror (SM) structure and a color on encapsulation (COE) technique in which the color filter layer 170 is disposed above the encapsulation unit 140 is applied to increase the light extraction efficiency. For example, the second area 122b of the anode 122 including a reflective layer serves as a side mirror SM so that light which is generated in the light emitting diode 120 to be discharged to the second area 122b is reflected and extracted in the front surface to improve the efficiency of the display device. Further, the color filter layer 170 and the black matrix 175 are disposed above the encapsulation unit 140 to remove the polarizer, so that the luminous efficiency can be improved.

However, in the SM structure, the second area 122b is added to the anode 122 so that the area of the anode 122 is substantially increased, thereby increasing the reflectance of the display panel. Further, according to the COE technique, the reflectance of the display panel is increased by the external light.

Therefore, according to the first example embodiment of the present disclosure, reflected light which is increased by applying the SM structure and the COE technique is utilized as a reflection mode in the AOD driving area AOD. Therefore, the disadvantage according to the AOD driving is improved and the power consumption of the display device can be improved.

To this end, in the AOD driving area AOD, an optical shutter 180 can be further disposed on the color filter layer 170, but it is not limited thereto and the optical shutter 180 can also be disposed on the color filter layer 170 in the normal area. At this time, an interlayer layer 185 can be disposed on the black matrix 175 of the first non-emission area NEA1 in which the optical shutter 180 is not disposed, but it is not limited thereto.

As long as the optical shutter 180 selectively blocks or transmits light, as the optical shutter, both a mechanical optical shutter and an electrophoretic optical shutter can be applied.

For example, the optical shutter 180 according to the first example embodiment of the present disclosure can include a first optical shutter 180a located so as to correspond to the first area 122a and the second area 122b of the anode 122 and a second optical shutter 180b located so as to correspond to the extending area 122e of the anode 122. The first optical shutter 180a and the second optical shutter 180b can be individually driven.

As described above, according to the first example embodiment of the present disclosure, the extending area 122e formed by extending the anode 122 is formed in the AOD driving area AOD and the optical shutter 180 is disposed to selectively open and close the emission areas EA1 and EA2 and the reflection area REA. Therefore, a reflection mode and a non-driving mode are implemented in addition to the self-emission mode, which will be described in more detail with reference to the drawing.

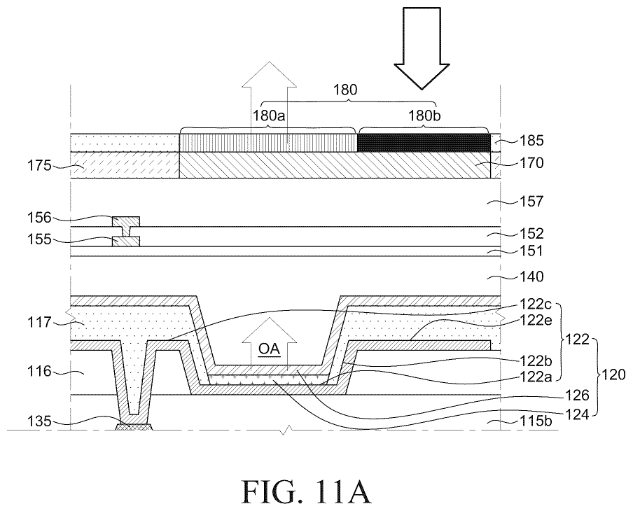

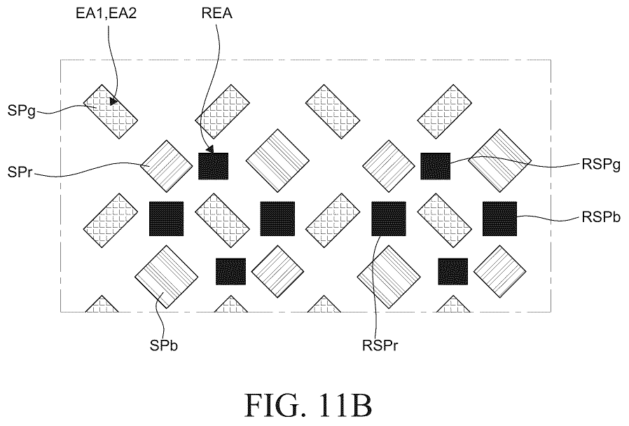

FIGS. 11A and 11B are views for explaining a self-emission mode of a display device according to a first example embodiment of the present disclosure.

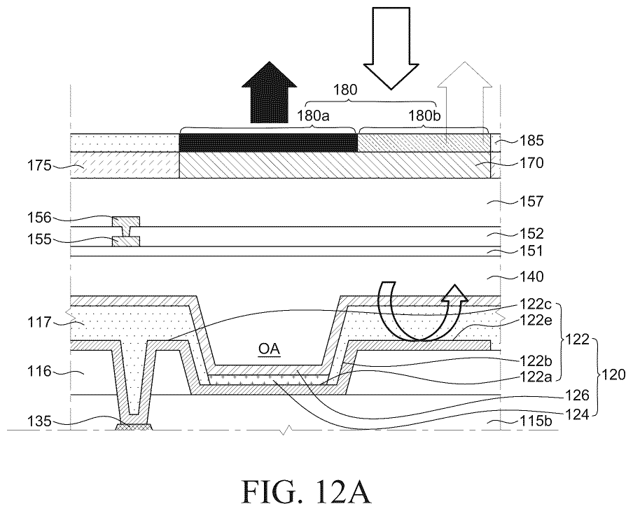

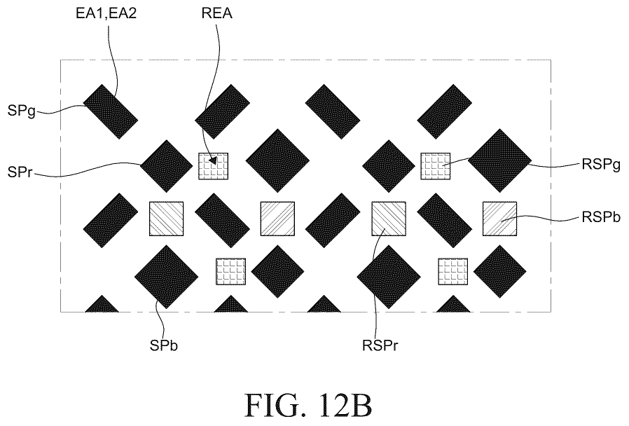

FIGS. 12A and 12B are views for explaining a reflection mode of a display device according to a first example embodiment of the present disclosure.

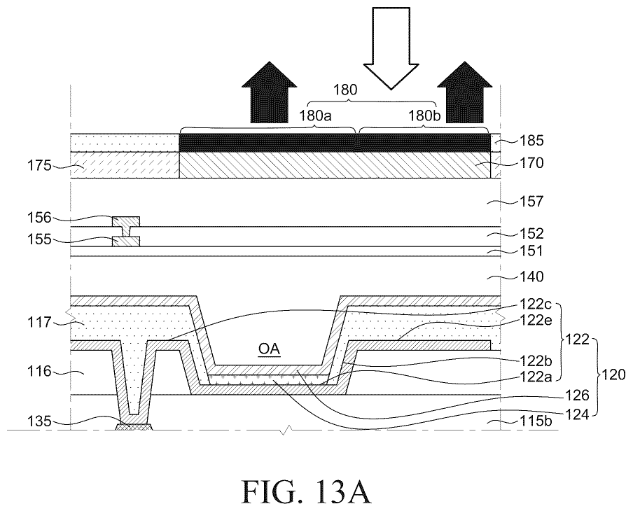

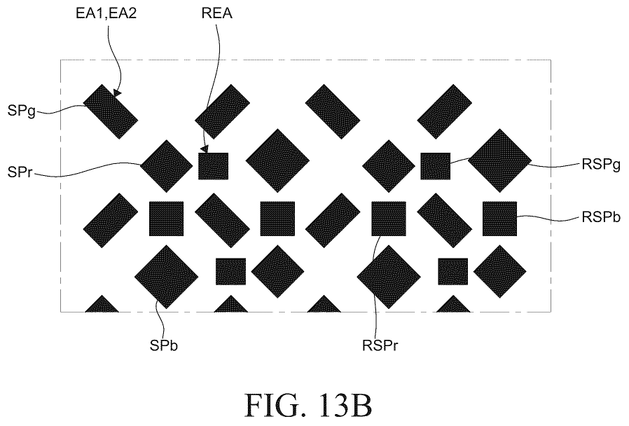

FIGS. 13A and 13B are views for explaining a non-driving mode of a display device according to a first example embodiment of the present disclosure.

In FIGS. 11A, 11B, 12A, 12B, 13A, and 13B, for the sake of convenience, configurations below the second planarization film 115b are omitted. The same configuration will be denoted with the same reference numeral. Here, the description for the same reference numeral can be understood by referring to the above description associated with FIGS. 1 to 7.

More specifically, FIGS. 11A, 12A, and 13A illustrate a partial cross-sectional structure including a behavior of light according to the driving of the light emitting diode 120 and the optical shutter 180 for the self-emission mode, the reflection mode, and the non-driving mode, respectively, in the AOD driving area AOD.

FIGS. 11B, 12B, and 13B illustrate emission and reflection of the sub pixel according to the driving of the light emitting diode 120 and the optical shutter 180 for the self-emission mode, the reflection mode, and the non-driving mode, respectively, in the AOD driving area AOD.

For example, the optical shutter 180 according to the first example embodiment of the present disclosure can include a first optical shutter 180a located so as to correspond to the first area 122a and the second area 122b of the anode 122 and a second optical shutter 180b located so as to correspond to the extending area 122e of the anode 122. The first optical shutter 180a and the second optical shutter 180b can be individually driven.

Referring to FIGS. 11A and 11B, in the self-emission mode, both the light emitting diode 120 and the first optical shutter 180a can be driven in the emission areas EA1 and EA2. For example, the light emitting diode 120 and the first optical shutter 180a can be turned on.

Further, in the reflection area REA, the second optical shutter 180b may not be driven. For example, the second optical shutter 180b can be turned off.

In this case, light emitted from the light emitting diode 120 passes through the color filter layer 170 and the first optical shutter 180a and as a result, the emission areas EA1 and EA2 of the sub pixels SPr, SPg, and SPb can display colors other than black.

In the meantime, the external light does not pass through the second optical shutter 180b and as a result, the reflection areas REA and the sub pixels RSPr, RSPg, and RSPb of the reflection area can display black.

As described above, according to the first example embodiment of the present disclosure, in the self-emission mode, the efficiency and the color purity of the light emitting diode 120 can be improved.

Referring to FIGS. 12A and 12B, in the reflection mode, both the light emitting diode 120 and the first optical shutter 180a may not be driven in the emission areas EA1 and EA2. For example, the light emitting diode 120 and the first optical shutter 180a can be turned off.

Further, in the reflection area REA, the second optical shutter 180b can be driven. For example, the second optical shutter 180b can be turned on.

In this case, the light emitting diode 120 does not emit light and the first optical shutter 180a is turned off and as a result, the emission areas EA1 and EA2 of the sub pixels SPr, SPg, and SPb can display black.

In the meantime, the external light passes through the second optical shutter 180b to be reflected by the extending area 122e of the anode 122 to go out and as a result, the reflection areas REA and the sub pixels RSPr, RSPg, and RSPb of the reflection area display colors other than black.

As described above, according to the first example embodiment of the present disclosure, in the reflection mode, in a state in which the light emitting diode 120 is turned off, images can be displayed through the reflection area REA so that the power consumption of the AOD driving area AOD can be minimized.

Referring to FIGS. 13A and 13B, in the non-driving mode, both the light emitting diode 120 and the first optical shutter 180a may not be driven in the emission areas EA1 and EA2. For example, the light emitting diode 120 and the first optical shutter 180a can be turned off.

Further, in the reflection area REA, the second optical shutter 180b may not be driven. For example, the second optical shutter 180b can be turned off.

In this case, the light emitting diode 120 does not emit light and the first optical shutter 180a is turned off and as a result, the emission areas EA1 and EA2 of the sub pixels SPr, SPg, and SPb can display black.

In the meantime, the external light may not pass through the second optical shutter 180b and as a result, the reflection area REA of the sub pixels RSPr, RSPg, and RSPb of the reflection area can display black.

As described above, according to the first example embodiment of the present disclosure, in the non-driving mode, in the state in which the light emitting diode 120 is turned off, both the emission areas EA1 and EA2 and the reflection area REA display black to implement full black.

In the meantime, according to the present disclosure, the optical shutter may not be provided in the emission area, which will be described in more detail with reference to a second example embodiment of the present disclosure.

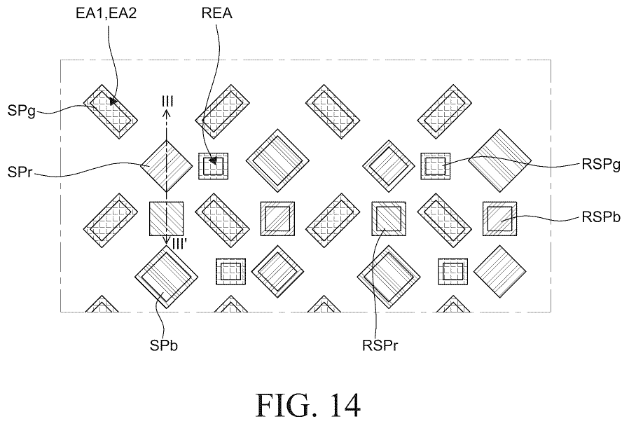

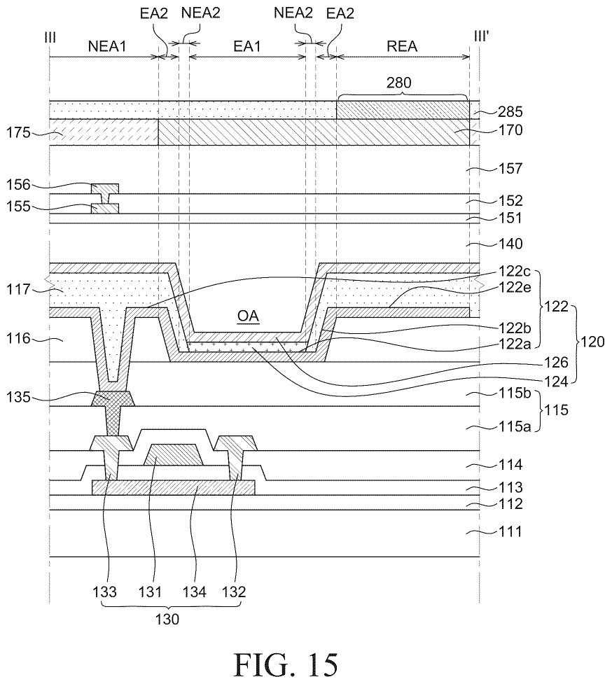

FIG. 14 is a view illustrating a pixel structure in an AOD driving area, in a display device according to a second example embodiment of the present disclosure. FIG. 15 is a cross-sectional view taken along the line III-III′ of FIG. 14.

A display device of the second example embodiment of FIGS. 14 and 15 does not include an optical shutter 280 in the emission areas EA1 and EA2, which is different from the first example embodiment of FIGS. 4 and 5 described above. However, other configurations are substantially the same so that a redundant description will be omitted or may be briefly provided. Here, the description for the same reference numeral can be understood by referring to the above description associated with FIGS. 1 to 7.

For example, FIGS. 14 and 15 illustrate a pixel structure and a part of a cross-sectional structure of one sub pixel, in the AOD driving area AOD.

For the convenience of description, in FIG. 14, sub pixels SPr, SPg, and SPb are defined with respect to an anode 122 which forms emission areas EA1 and EA2, but it is not limited thereto. Here, the emission areas EA1 and EA2 can correspond to the sub pixels SPr, SPg, and SPb, but the present disclosure is not limited thereto. In the meantime, in the AOD driving area AOD of FIG. 4, sub pixels RSPr, RSPg, and RSPb of a reflection area can be added in addition to the sub pixels SPr, SPg, and SPb.

Referring to FIGS. 14 and 15, in a display panel according to the second example embodiment of the present disclosure, a black matrix 175 can be disposed on the touch planarization film 157.

The black matrix 175 can be located so as to correspond to the first non-emission area NEA1.

The color filter layer 170 can be disposed in the emission areas EA1 and EA2, the second non-emission area NEA2, and the reflection area REA between the black matrixes 175.

According to the second example embodiment of the present disclosure, an optical shutter 280 can be further disposed on the color filter layer 170 of the reflection area REA. For example, the optical shutter 280 according to the second example embodiment of the present disclosure can be located so as to correspond to the extending area 122e of the anode 122.

Further, the optical shutter 280 is not disposed on the black matrix 175 of the first non-emission area NEA1 and the color filter layer 170 of the emission areas EA1 and EA2 and the second non-emission area NEA2, but an interlayer layer 285 can be disposed instead. However, the present disclosure is not limited thereto.

As described above, according to the second example embodiment of the present disclosure, the extending area 122e formed by extending the anode 122 is formed in the AOD driving area AOD and the optical shutter 280 is disposed to correspond to the extending area 122e to selectively open and close the reflection area REA. Therefore, a reflection mode can be implemented in addition to the self-emission mode, which will be described in more detail with reference to the drawings.

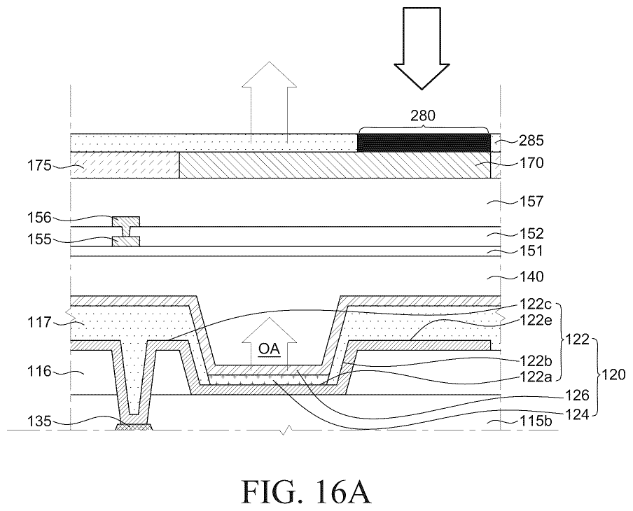

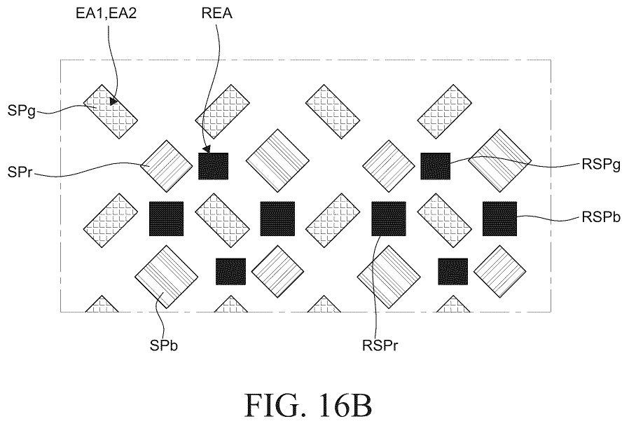

FIGS. 16A and 16B are views for explaining a self-emission mode of a display device according to the second example embodiment of the present disclosure.

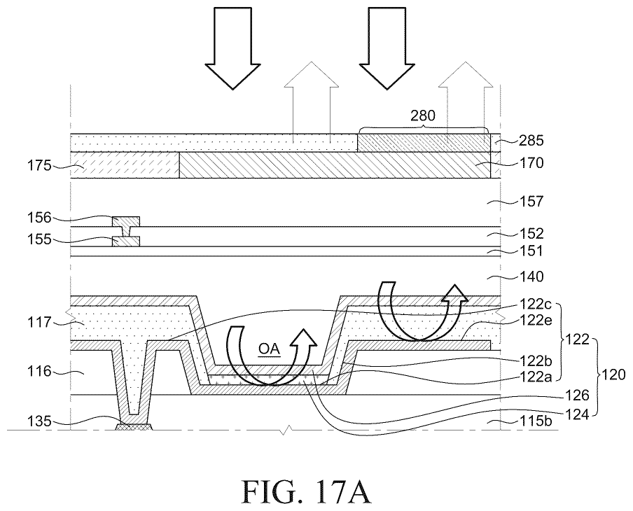

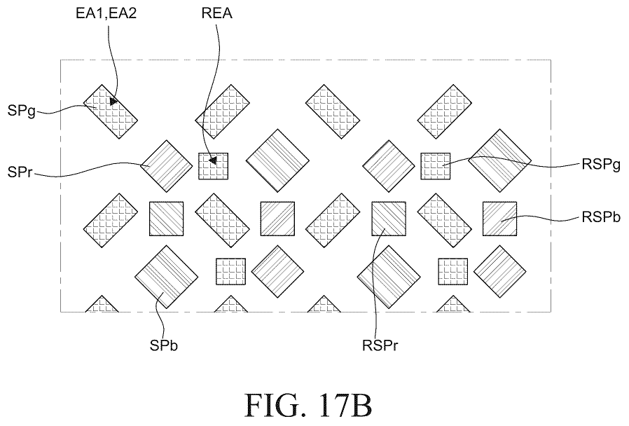

FIGS. 17A and 17B are views for explaining a reflection mode of a display device according to the second example embodiment of the present disclosure.

At this time, in FIGS. 16A, 16B, 17A, and 17B, for the sake of convenience, configurations below the second planarization film 115b are omitted. The same configuration will be denoted with the same reference numeral. Here, the description for the same reference numeral can be understood by referring to the above description associated with FIGS. 1 to 7, 14, and 15.

Here, FIGS. 16A and 17A illustrate a partial cross-sectional structure including a behavior of light according to the driving of the light emitting diode 120 and the optical shutter 280 for the self-emission mode and the reflection mode, in the AOD driving area AOD.

FIGS. 16B and 17B illustrate emission and reflection of the sub pixel according to the driving of the light emitting diode 120 and the optical shutter 280 for the self-emission mode and the reflection mode, in the AOD driving area AOD.

For example, the optical shutter 280 according to the second example embodiment of the present disclosure can be located so as to correspond to the extending area 122e of the anode 122.

Referring to FIGS. 16A and 16B, in the self-emission mode, the light emitting diode 120 can be driven in the emission areas EA1 and EA2. For example, the light emitting diode 120 can be turned on.

Further, in the reflection area REA, the optical shutter 280 may not be driven. For example, the optical shutter 280 can be turned off.

In this case, light emitted from the light emitting diode 120 passes through the color filter layer 170 and the interlayer layer 285 thereabove and as a result, the emission areas EA1 and EA2 of the sub pixels SPr, SPg, and SPb can display colors other than black.

In the meantime, the external light does not pass through the optical shutter 280 and as a result, the reflection area REA of the sub pixels RSPr, RSPg, and RSPb of the reflection area can display black.

As described above, according to the second example embodiment of the present disclosure, in the self-emission mode, the efficiency and the color purity of the light emitting diode 120 can be improved.

Referring to FIGS. 17A and 17B, in the reflection mode, the light emitting diode 120 may not be driven in the emission areas EA1 and EA2. For example, the light emitting diode 120 can be turned off.

Further, in the reflection area REA, the optical shutter 280 can be driven. For example, the optical shutter 280 can be turned on.

In this case, the light emitting diode 120 does not emit light. However, the interlayer layer 285 is located above the light emitting diode 120, instead of the optical shutter 280, so that external light passes through the interlayer layer 285 and the color filter layer 170 to be reflected by the first area 122a and the second area 122b of the anode 122 to go out. As a result, the emission areas EA1 and EA2 of the sub pixels SPr, SPg, and SPb can display colors other than black.

Further, the external light passes through the optical shutter 280 to be reflected by the extending area 122e of the anode 122 to go out and as a result, the reflection areas REA and the sub pixels RSPr, RSPg, and RSPb of the reflection area display colors other than black.

As described above, according to the second example embodiment of the present disclosure, in the reflection mode, in a state in which the light emitting diode 120 is turned off, an image can be displayed through the emission areas EA1 and EA2 and the reflection area REA by the external light so that the power consumption of the AOD driving area AOD can be minimized.

In the meantime, according to the present disclosure, the reflection area may not be provided, which will be described in more detail with reference to a third example embodiment of the present disclosure.

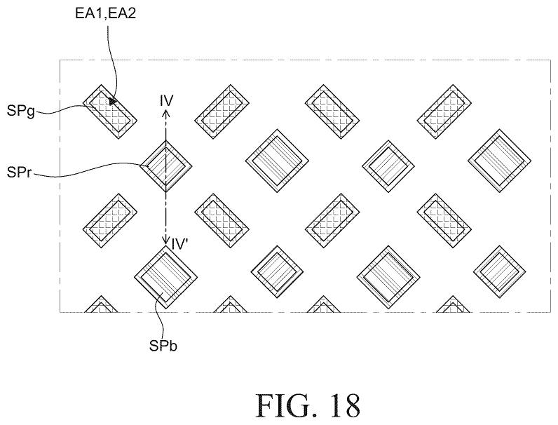

FIG. 18 is a view illustrating a pixel structure in an AOD driving area, in a display device according to a third example embodiment of the present disclosure.

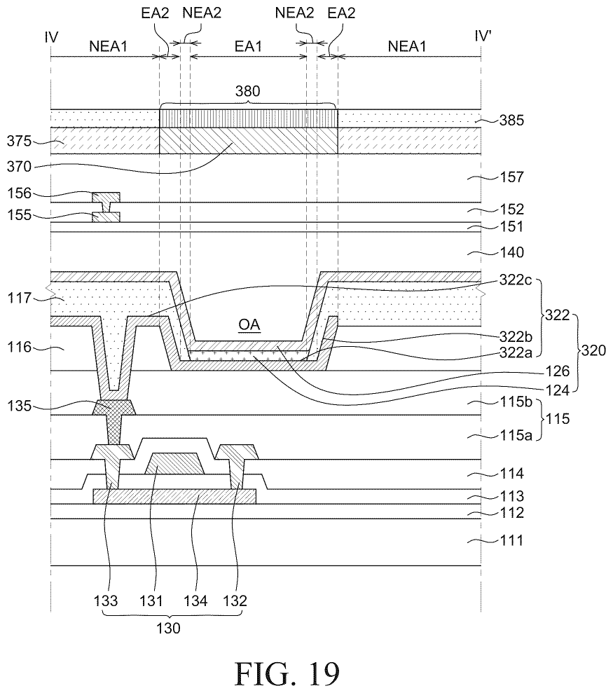

FIG. 19 is a cross-sectional view taken along the line IV-IV′ of FIG. 18.

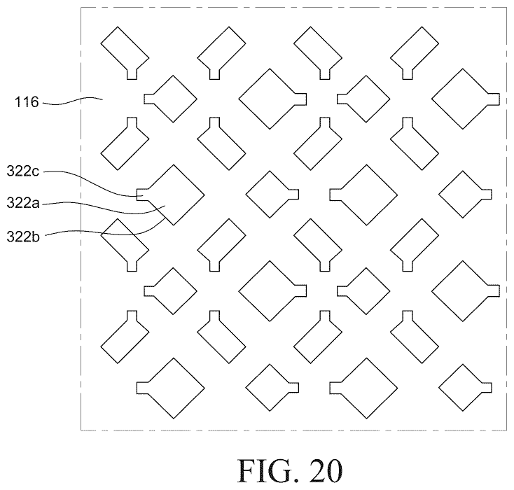

FIG. 20 is a view illustrating a planar shape of an anode according to the third example embodiment of the present disclosure.

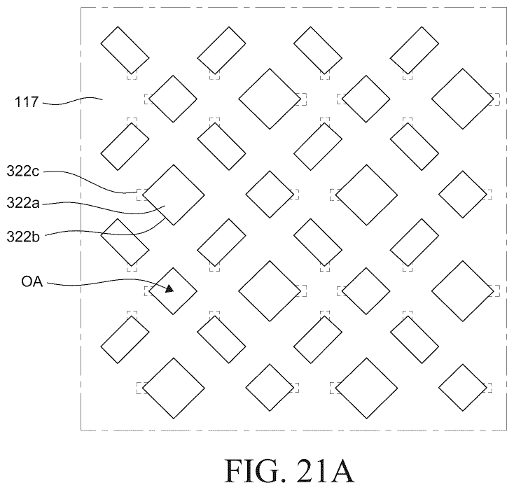

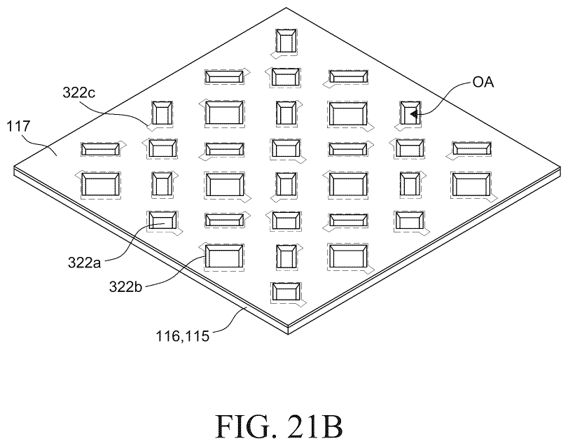

FIGS. 21A and 21B are views illustrating a planar shape of a bank according to the third example embodiment of the present disclosure.

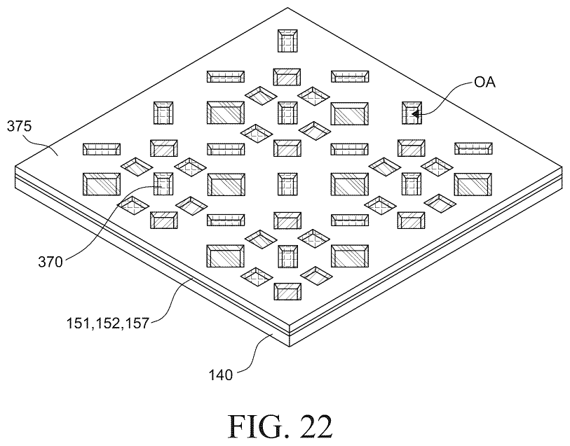

FIG. 22 is a perspective view illustrating a pixel structure above an encapsulation unit in a display panel according to the third example embodiment of the present disclosure.

A display device according to the third example embodiment of FIGS. 18 to 22 does not include a reflection area and a sub pixel of the reflection area, which is different from the first example embodiment of FIGS. 4 to 10 described above. However, other configurations are substantially the same so that a redundant description will be omitted or may be briefly provided. Here, the description for the same reference numeral can be understood by referring to the above description associated with FIGS. 1 to 10.

For example, FIGS. 18 and 19 illustrate a pixel structure and a part of a cross-sectional structure of one sub pixel, in the AOD driving area AOD.

For the sake of convenience, in FIG. 18, sub pixels SPr, SPg, and SPb are defined with respect to an anode 322 which forms emission areas EA1 and EA2, but it is not limited thereto. Here, the emission areas EA1 and EA2 can correspond to the sub pixels SPr, SPg, and SPb, but are not limited thereto.

FIG. 21A is a plan view illustrating an example that a second bank 117 is disposed above the anode 322 of FIG. 20 and FIG. 21B is a perspective view of FIG. 21A.

FIG. 22 illustrates an example that an encapsulation unit 140, a touch buffer film 151, a touch insulating film 152, a touch planarization film 157, a color filter layer 370, and a black matrix 375 are sequentially disposed above the second bank 117 of FIGS. 21A and 21B.

Referring to FIG. 18, the display panel of the third example embodiment of the present disclosure can include a plurality of pixels configured by a first sub pixel SPr, a second sub pixel SPg, and a third sub pixel SPb.

According to the third example embodiment of the present disclosure, unlike the first and second example embodiments described above, the anode 322 does not have an extending area so that a reflection area is not added in addition to the emission areas EA1 and EA2 (see FIG. 20).

Referring to FIG. 19, the light emitting diode 320 which is electrically connected to the connection electrode 135 through a contact hole can be disposed above the second planarization film 115b in which the first bank 116 is not disposed.

At this time, for example, the light emitting diode 320 can include an anode 322 connected to the drain electrode 133 of the driving thin film transistor 130, a plurality of organic layers 124 disposed on the anode 322, and a cathode 126 disposed on the organic layers 124.

Further, for example, the anode 322 can include a first area 322a which is disposed on the second planarization film 115b to be in contact with the second planarization film 115b and a second area 322b which extends from the first area 322a to be disposed on the side surface of the first bank 116. The first area 322a has a surface substantially parallel to a surface of the substrate 111 and the second area 322b has a surface which has a predetermined angle with respect to the substrate 111. Accordingly, a surface of the second area 322b may not be parallel to the surface of the substrate 111 (see FIGS. 20, 21A, and 21B).

Further, for example, the anode 322 can include a third area 322c which extends from the second area 322b in one direction to be electrically connected to the connection electrode 135 through a contact hole (see FIGS. 20, 21A, and 21B).

The anode 322 can include a reflective layer which is formed of a reflective metal.

As described above, the second area 122b according to the third example embodiment of the present disclosure can be disposed on the side surface of the first bank 116 along a shape of the side surface of the first bank 116. Accordingly, the second area 322b of the anode 322 including the reflective layer can serve as a side mirror SM. Accordingly, the emission areas EA1 and EA2 according to the third example embodiment of the present disclosure can further include a reflective emission area EA2 by the SM structure, in addition to the main emission area EA1.

In the meantime, the black matrix 375 can be disposed above the touch planarization film 157 (see FIG. 22).

The black matrix 375 of the third example embodiment of the present disclosure can be located so as to correspond to the first non-emission area NEA1. The color filter layer 370 can be disposed in the emission areas EA1 and EA2 and the second non-emission area NEA2 between the black matrixes 375 (see FIG. 22).

In the AOD driving area AOD, an optical shutter 380 can be further disposed on the color filter layer 370. At this time, an interlayer layer 385 can be disposed on the black matrix 375 of the first non-emission area NEA1 in which the optical shutter 380 is not disposed, but it is not limited thereto.

For example, the optical shutter 380 according to the third example embodiment of the present disclosure can be located so as to correspond to a first area 322a and a second area 322b of the anode 322.

As described above, according to the third example embodiment of the present disclosure, the optical shutter 380 is disposed in the AOD driving area AOD to selectively open and close the emission areas EA1 and EA2 to implement the reflection mode and the non-driving mode in addition to the self-emission mode. This will be described in more detail with reference to the drawings.

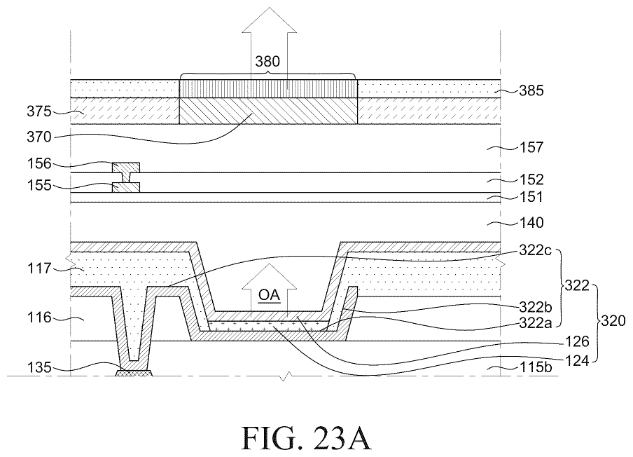

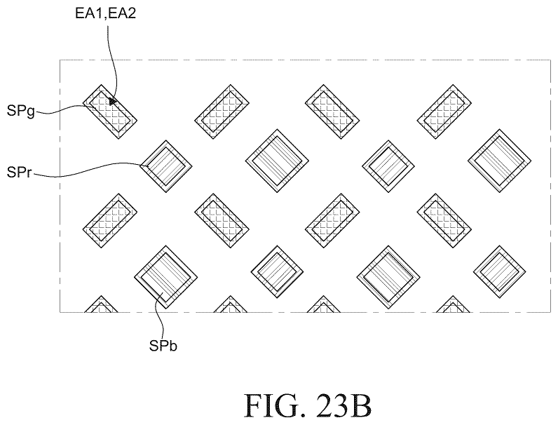

FIGS. 23A and 23B are views for explaining a self-emission mode of a display device according to the third example embodiment of the present disclosure.

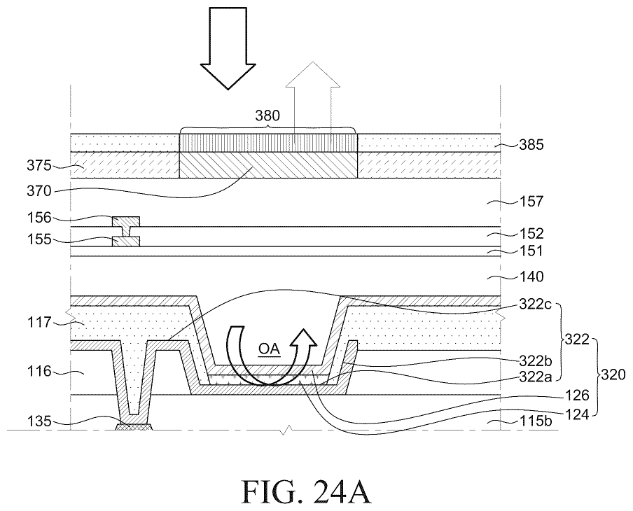

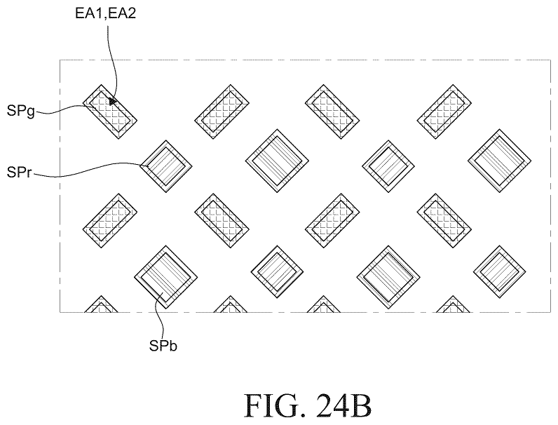

FIGS. 24A and 24B are views for explaining a reflection mode of the display device according to the third example embodiment of the present disclosure.

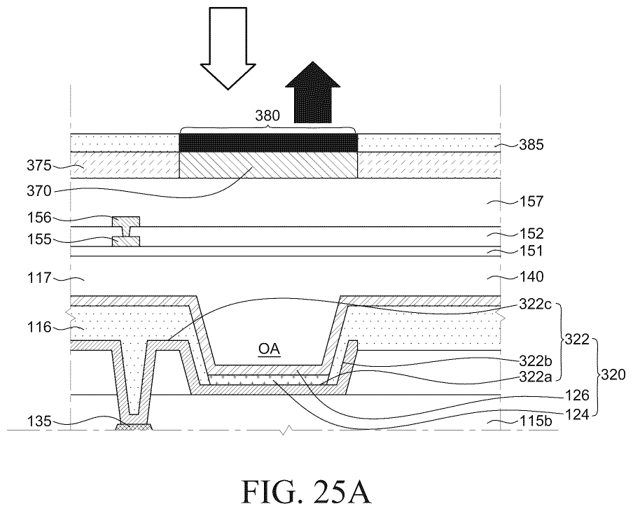

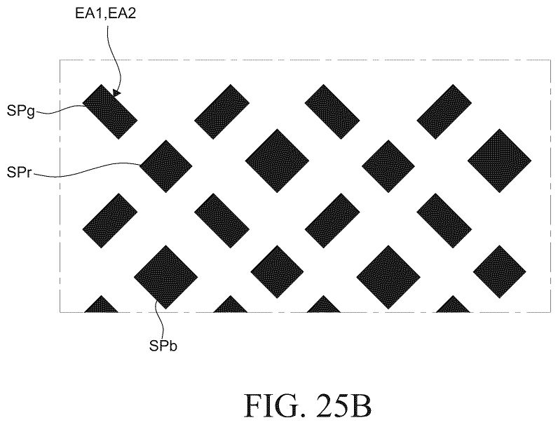

FIGS. 25A and 25B are views for explaining a non-driving mode of the display device according to the third example embodiment of the present disclosure.

In FIGS. 23A, 23B, 24A, 24B, 25A, and 25B, for the sake of convenience, configurations below the second planarization film 115b are omitted. The same configuration will be denoted with the same reference numeral. Here, the description for the same reference numeral can be understood by referring to the above description associated with FIGS. 1 to 7.

Particularly, FIGS. 23A, 24A, and 25A illustrate a partial cross-sectional structure including a behavior of light according to the driving of the light emitting diode 320 and the optical shutter 380 for the self-emission mode, the reflection mode, and the non-driving mode, respectively, in the AOD driving area AOD.

FIGS. 23B, 24B, and 25B illustrate emission and reflection of the sub pixel according to the driving of the light emitting diode 320 and the optical shutter 380 for the self-emission mode, the reflection mode, and the non-driving mode, respectively, in the AOD driving area AOD.

For example, the optical shutter 380 according to the third example embodiment of the present disclosure can be located so as to correspond to a first area 322a and a second area 322b of the anode 322.

Referring to FIGS. 23A and 23B, in the self-emission mode, both the light emitting diode 320 and the optical shutter 380 can be driven in the emission areas EA1 and EA2. For example, the light emitting diode 320 and the optical shutter 380 can be turned on.

In this case, light emitted from the light emitting diode 320 passes through the color filter layer 370 and the optical shutter 380 thereabove and as a result, the emission areas EA1 and EA2 of the sub pixels SPr, SPg, and SPb can display colors other than black.

As described above, according to the third example embodiment of the present disclosure, in the self-emission mode, the efficiency and the color purity of the light emitting diode 320 can be improved.

Referring to FIGS. 24A and 24B, in the reflection mode, the light emitting diode 320 may not be driven and the optical shutter 380 can be driven in the emission areas EA1 and EA2. For example, the light emitting diode 320 can be turned off and the optical shutter 380 can be turned on.

In this case, the light emitting diode 320 does not emit light. However, the optical shutter 380 is turned on, so that external light passes through the optical shutter 380 and the color filter layer 370 to be reflected by the first area 322a and the second area 322b of the anode 322 to go out. As a result, the emission areas EA1 and EA2 of the sub pixels SPr, SPg, and SPb can display colors other than black.

As described above, according to the third example embodiment of the present disclosure, in the reflection mode, in a state in which the light emitting diode 320 is turned off, an image can be displayed through the emission areas EA1 and EA2 so that the power consumption of the AOD driving area AOD can be minimized.

Referring to FIGS. 25A and 25B, in the non-driving mode, both the light emitting diode 320 and the optical shutter 380 may not be driven in the emission areas EA1 and EA2. For example, the light emitting diode 320 and the optical shutter 380 can be turned off.

In this case, the light emitting diode 320 does not emit light and the optical shutter 380 is turned off and as a result, the emission areas EA1 and EA2 of the sub pixels SPr, SPg, and SPb can display black.

As described above, according to the third example embodiment of the present disclosure, in the non-driving mode, in the state in which the light emitting diode 320 is turned off, the emission areas EA1 and EA2 can display black to implement full black.

In the meantime, according to the present disclosure, an optical lens can be provided below the color filter layer, which will be described in more detail with a fourth example embodiment of the present disclosure.

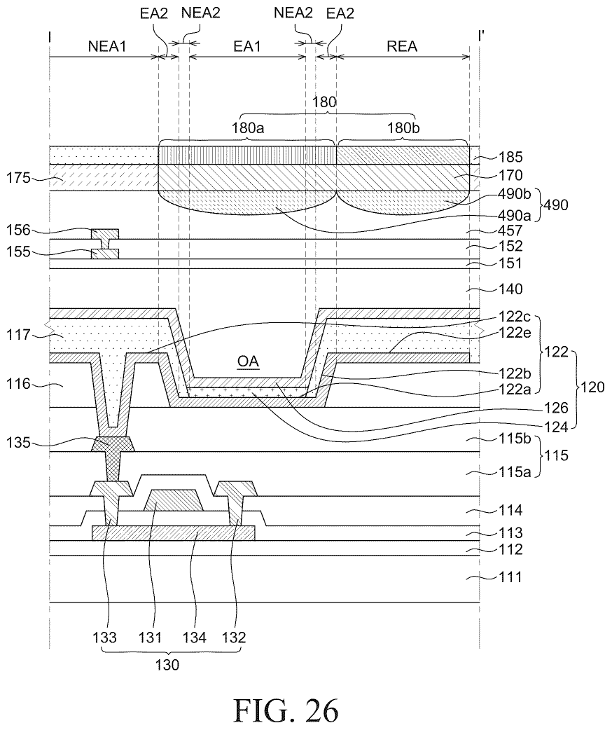

FIG. 26 is a view illustrating a part of a cross-section of a display panel according to a fourth example embodiment of the present disclosure.

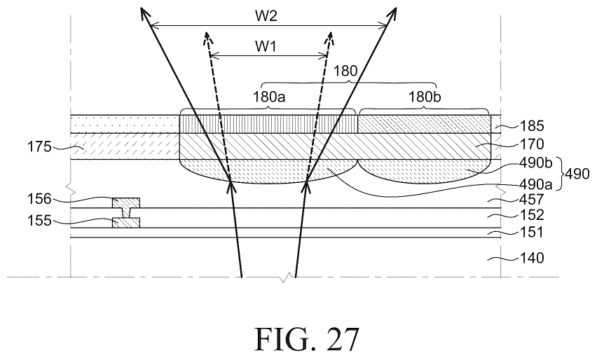

FIG. 27 is a view illustrating a part of a lamination structure of FIG. 26.

A display device according to the fourth example embodiment of FIGS. 26 and 27 includes an optical lens 490 below the color filter layer 170, which is different from the first example embodiment of FIG. 5 described above, but other configurations are substantially the same so that a redundant description will be omitted or may be briefly provided. Here, the description for the same reference numeral can be understood by referring to the above description associated with FIGS. 1 to 7.

Referring to FIGS. 26 and 27, in the display device according to the fourth example embodiment of the present disclosure, a black matrix 175 can be disposed on a touch planarization film 457.

The black matrix 175 can be located so as to correspond to the first non-emission area NEA1.

The color filter layer 170 can be disposed in the emission areas EA1 and EA2, the second non-emission area NEA2, and the reflection area REA between the black matrixes 175.

In the meantime, the display device according to the fourth example embodiment of the present disclosure includes an optical lens 490 disposed between the touch planarization film 457 and the black matrix 175, and the color filter layer 170.

For example, the optical lens 490 can be a convex lens which protrudes toward the substrate 110.

At this time, the optical lens 490 can include a first optical lens 490a located so as to correspond to the emission areas EA1 and EA2 and the second non-emission area NEA2 and a second optical lens 490b located so as to correspond to the reflection area REA.

The color filter layer 170 is disposed above the first optical lens 490a and the second optical lens 490b and a first optical shutter 180a and a second optical shutter 180b can be disposed thereabove.

The first optical lens 490a and the second optical lens 490b can be configured with the same material, but are not limited thereto and can be configured with different materials.

The first optical lens 490a and the second optical lens 490b can have the same refractive index, but are not limited thereto and can have different refractive indexes.

For example, the optical lens 490 can have a refractive index lower than that of the touch planarization film 457. For example, the optical lens 490 can have a relatively low refractive index of approximately 1.5 and the touch planarization film 457 can have a relatively high refractive index of approximately 1.8.

According to the fourth example embodiment of the present disclosure, as the optical lens 490 having a lower refractive index is disposed on the touch planarization film 457 having a higher refractive index so that the path of light emitted from the light emitting diode 120 is expanded. Therefore, the visibility and the viewing angle of the display device can be improved. For example, in the example embodiments in which the optical lens 490 is not disposed, a width of light which passes through the color filter layer 170 is W1. However, it is understood that in the fourth example embodiment of the present disclosure in which the optical lens 490 is disposed, the path of light is expanded by the optical lens 490 so that the width of light which passes through the color filter layer 170 is increased to W2.

The example embodiments of the present disclosure can also be described as follows:

According to an aspect of the present disclosure, there is provided a display device. The display device includes a substrate which includes a first active area and a second active area, a planarization film disposed above the substrate, a first bank disposed on the planarization film, an anode which is disposed on the planarization film, including a side surface of the first bank, a second bank disposed above the first bank and the anode while covering a part of the anode and the first bank, an organic layer and a cathode disposed above the anode, an encapsulation unit disposed above the cathode, a black matrix and a color filter layer disposed above the encapsulation unit and an optical shutter which is disposed above the color filter layer of the second active area, in the second active area, the anode can include an extending area which partially extends in one direction to form a reflection area.

The second active area can be an always-on-display (AOD) driving area.

The first active area can be configured by a plurality of sub pixels having emission areas, and the second active area can be configured by a plurality of reflection area sub pixels having the reflection area in addition to the sub pixels.

The reflection area sub pixel can be adjacent to the sub pixel to extend from each sub pixel.

The anode includes a first area which is disposed on the planarization film to be in contact with the planarization film, a second area which extends from the first area to be disposed on a side surface of the first bank and has a surface having a predetermined angle with respect to the substrate and a third area which extends from the second area in the other direction to be electrically connected to a thin film transistor through a contact hole.

The extending area can extend from the second area in the one direction to be in contact with a top surface of the first bank.

The second bank can cover a part of the first area and all of the second area, the third area, and the extending area.

The second bank can include an open area formed by removing a part corresponding to a main emission area.

A sub pixel of the first active area can include a plurality of emission areas and a plurality of non-emission areas and a sub pixel of the second active area can have the plurality of emission areas, the plurality of non-emission areas, and the reflection area.

The emission area can include the main emission area and a reflective emission area, and the non-emission area includes a first non-emission area located to correspond to the first bank in which the second area and the extending area are not located and a second non-emission area which is located between the main emission area and the reflective emission area.

The reflection area can extend from the main emission area between the main emission areas of adjacent sub pixels.

The display device can further comprise touch configurations disposed above the encapsulation unit.

The black matrix can be located to correspond to the first non-emission area.

The color filter layer can be located to correspond to the emission area, the second non-emission area, and the reflection area between the black matrixes.

The display device can further comprise an interlayer layer disposed on the black matrix.

The optical shutter can include a first optical shutter located to correspond to the first area and the second area and a second optical shutter located to correspond to the extending area, and the first optical shutter and the second optical shutter can be individually driven.

In the second active area, a light emitting diode and the first optical shutter can be turned on and the second optical shutter can be turned off to implement a self-emission mode, in the second active area, the light emitting diode and the first optical shutter can be turned off and the second optical shutter can be turned on to implement a reflection mode, and in the second active area, all of the light emitting diode, the first optical shutter, and the second optical shutter can be turned off to implement a non-driving mode.

The optical shutter can be located to correspond to the extending area.

In the second active area, the light emitting diode can be turned on and the optical shutter can be turned off to implement a self-emission mode and in the second active area, the light emitting diode can be turned off and the optical shutter can be turned on to implement a reflection mode.

According to another aspect of the present disclosure, there is provided a display device. The display device includes a substrate including an always-on-display (AOD) driving area, a planarization film disposed above the substrate, a first bank disposed on the planarization film, an anode which is disposed on the planarization film, including a side surface of the first bank, a second bank disposed above the first bank and the anode while covering a part of the anode and the first bank, an organic layer and a cathode disposed above the anode, an encapsulation unit disposed above the cathode, a black matrix and a color filter layer disposed above the encapsulation unit and an optical shutter disposed above the color filter layer of the AOD driving area.

A sub pixel of the AOD driving area can have a plurality of emission areas and a plurality of non-emission areas.

The anode can include a first area which is disposed on the planarization film to be in contact with the planarization film, a second area which extends from the first area to be disposed on a side surface of the first bank and has a surface having a predetermined angle with respect to the substrate and a third area which extends from the second area in one direction to be electrically connected to a thin film transistor.

The emission area can include a main emission area and a reflective emission area, and the non-emission area can include a first non-emission area located to correspond to the first bank in which the second area is not located and a second non-emission area which is located between the main emission area and the reflective emission area.

The black matrix can be located to correspond to the first non-emission area, and the color filter layer can be located to correspond to the emission area and the second non-emission area between the black matrixes.

The optical shutter can be located to correspond to the color filter layer.

In the AOD driving area, a light emitting diode and the optical shutter can be turned on to implement a self-emission mode, in the AOD driving area, the light emitting diode can be turned off and the optical shutter can be turned on to implement a reflection mode, and in the AOD driving area, the light emitting diode and the optical shutter can be turned off to implement a non-driving mode.

The display device can further comprise an optical lens disposed below the color filter layer.

The optical lens can be configured by a convex lens protruding toward the substrate.

The optical lens can have a refractive index lower than that of an insulating film disposed therebelow.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a first active area and a second active area;
a planarization film disposed on the substrate;
a first bank disposed on the planarization film;
an anode disposed on the planarization film and a side surface of the first bank;
a second bank disposed on the first bank and the anode while covering a part of the anode and the first bank;
an organic layer and a cathode disposed on the anode;
an encapsulation unit disposed on the cathode;
a black matrix and a color filter layer disposed on the encapsulation unit; and
an optical shutter disposed on the color filter layer of the second active area,
wherein in the second active area, the anode includes an extending area partially extending in one direction to form a reflection area.

2. The display device according to claim 1, wherein the second active area is an always-on-display (AOD) driving area.

3. The display device according to claim 1, wherein the first active area is configured by a plurality of sub pixels having emission areas, and the second active area is configured by a plurality of reflection area sub pixels having the reflection area in addition to the plurality of sub pixels.

4. The display device according to claim 3, wherein the reflection area sub pixel is adjacent to the sub pixel to extend from each sub pixel.

5. The display device according to claim 1, wherein the anode includes:
a first area disposed on the planarization film to be in contact with the planarization film;
a second area extending from the first area to be disposed on a side surface of the first bank and including a surface having a predetermined angle with respect to the substrate; and
a third area extending from the second area in another direction to be electrically connected to a thin film transistor through a contact hole.

6. The display device according to claim 5, wherein the extending area extends from the second area in the one direction to be in contact with a top surface of the first bank.

7. The display device according to claim 5, wherein the second bank covers a part of the first area and all of the second area, the third area, and the extending area.

8. The display device according to claim 5, wherein the second bank includes an open area formed by removing a part corresponding to a main emission area.

9. The display device according to claim 8, wherein a sub pixel of the first active area includes a plurality of emission areas and a plurality of non-emission areas, and a sub pixel of the second active area has the plurality of emission areas, the plurality of non-emission areas, and the reflection area.

10. The display device according to claim 9, wherein the emission area includes the main emission area and a reflective emission area, and
wherein the non-emission area includes:
a first non-emission area located to correspond to the first bank in which the second area and the extending area are not located; and
a second non-emission area located between the main emission area and the reflective emission area.

11. The display device according to claim 9, wherein the reflection area extends from the main emission area between the main emission areas of adjacent sub pixels.

12. The display device according to claim 1, further comprising:
a plurality of touch configurations disposed on the encapsulation unit.

13. The display device according to claim 10, wherein the black matrix is located to correspond to the first non-emission area.

14. The display device according to claim 13, wherein the color filter layer is located to correspond to the emission area, the second non-emission area, and the reflection area between the black matrixes.

15. The display device according to claim 1, further comprising:
an interlayer layer disposed on the black matrix.

16. The display device according to claim 5, wherein the optical shutter includes:
a first optical shutter located to correspond to the first area and the second area; and
a second optical shutter located to correspond to the extending area, and
wherein the first optical shutter and the second optical shutter are individually driven.

17. The display device according to claim 16, wherein in the second active area, a light emitting diode and the first optical shutter are turned on and the second optical shutter is turned off to implement a self-emission mode,
in the second active area, the light emitting diode and the first optical shutter are turned off and the second optical shutter is turned on to implement a reflection mode, and
in the second active area, all of the light emitting diode, the first optical shutter, and the second optical shutter are turned off to implement a non-driving mode.

18. The display device according to claim 5, wherein the optical shutter is located to correspond to the extending area.

19. The display device according to claim 18, wherein in the second active area, the light emitting diode is turned on and the optical shutter is turned off to implement a self-emission mode, and
in the second active area, the light emitting diode is turned off and the optical shutter is turned on to implement a reflection mode.

20. The display device according to claim 1, further comprising:
an optical lens disposed below the color filter layer.

21. A display device, comprising:
a substrate including an always-on-display (AOD) driving area;
a planarization film disposed on the substrate;
a first bank disposed on the planarization film;
an anode disposed on the planarization film and a side surface of the first bank;
a second bank disposed on the first bank and the anode while covering a part of the anode and the first bank;
an organic layer and a cathode disposed on the anode;
an encapsulation unit disposed on the cathode;
a black matrix and a color filter layer disposed on the encapsulation unit; and
an optical shutter disposed on the color filter layer of the AOD driving area.

22. The display device according to claim 21, wherein a sub pixel of the AOD driving area has a plurality of emission areas and a plurality of non-emission areas.

23. The display device according to claim 22, wherein the anode includes:
a first area disposed on the planarization film to be in contact with the planarization film;
a second area extending from the first area to be disposed on a side surface of the first bank and including a surface having a predetermined angle with respect to the substrate; and
a third area extending from the second area in one direction to be electrically connected to a thin film transistor.

24. The display device according to claim 23, wherein the emission area includes a main emission area and a reflective emission area, and
wherein the non-emission area includes:
a first non-emission area located to correspond to the first bank in which the second area is not located; and
a second non-emission area located between the main emission area and the reflective emission area.

25. The display device according to claim 24, wherein the black matrix is located to correspond to the first non-emission area, and the color filter layer is located to correspond to the emission area and the second non-emission area between the black matrixes.

26. The display device according to claim 25, wherein the optical shutter is located to correspond to the color filter layer.

27. The display device according to claim 26, wherein in the AOD driving area, a light emitting diode and the optical shutter are turned on to implement a self-emission mode,
in the AOD driving area, the light emitting diode is turned off and the optical shutter is turned on to implement a reflection mode, and
in the AOD driving area, the light emitting diode and the optical shutter are turned off to implement a non-driving mode.

28. The display device according to claim 21, further comprising:
an optical lens disposed below the color filter layer.

29. The display device according to claim 28, wherein the optical lens is configured by a convex lens protruding toward the substrate.

30. The display device according to claim 28, wherein the optical lens has a refractive index lower than a refractive index of an insulating film disposed therebelow.
